(19) United States
(12) Patent Application Publication
(10) Pub. No.: US 2026/0334126 A1
(43) Pub. Date: Oct. 22, 2026

(54) THERMALLY CONTROLLED CHAMBER DISCONNECT

(71) Applicant: Lam Research Corporation, Fremont, CA (US)

(72) Inventors: Jorge Reyes, Tigard, OR (US); Thomas M. Pratt, Los Gatos, CA (US); Chirag Raghunath Shivdas, Ahmedabad (IN); Curtis Warren Bailey, West Linn, OR (US); Emile C. Draper, Molalla, OR (US); Dustin Zachary Austin, Tigard, OR (US)

(21) Appl. No.: 19/158,382

(22) PCT Filed: Feb. 22, 2024
(86) PCT No.: PCT/US2024/016897

§ 371 Date: Aug. 20, 2025

Related U.S. Application Data
(60) Provisional application No. 63/486,854, filed on Feb. 24, 2023.

(51) Int. Cl. H10P 72/00; C23C 16/448; C23C 16/455; C23C 16/52; H01J 37/32

(52) U.S. Cl. CPC H10P 72/0402; C23C 16/4481; C23C 16/45561; C23C 16/52; H01J 37/32449; H01J 37/32807; H01J 37/32935; H10P 72/0421; H10P 72/0458; H10P 72/0462; H10P 72/0602

(57) ABSTRACT

An apparatus includes first and second assemblies. The first assembly includes a first disconnect having a first conduit connected thereto, and a temperature-controlled enclosure in contact with the first conduit. The first temperature-controlled enclosure is connected to a first part of a process chamber and includes a heater. The second assembly is connected to a second part of the process chamber, and includes a second disconnect having a second conduit connected thereto. At least one of the first and second parts is moveable between at least two configurations. In one configuration, the first and second parts are spaced apart. In another configuration, the first and second disconnects are fluidically connected to form, via the first and second conduits, a fluidic passageway spanning across a contact interface between the first and second parts. The temperature-controlled enclosure is configured, via the first heater, to transfer thermal energy to the first conduit.

### BACKGROUND

Semiconductor manufacturing typically involves one or more process operations to deposit and/or etch a structure on or in a semiconductor wafer (or substrate). Such processes may employ one or more vapor-phase delivery systems in which vapor-phase and sometimes gas precursors are reacted with and/or on a surface of a substrate to deposit material thereon or to remove material therefrom. Although many forms of vapor-phase delivery systems exist, they are generally configured to provide controlled gas flow and delivery of precursors, which may otherwise be in a liquid-or solid-phase at ambient temperature and atmospheric pressure conditions. This difference in phases between storage and supply into a process volume (or chamber) presents numerous challenges thwarting efforts to prevent undesired condensation, deposition, etching, particle generation, etc., in and/or from at least the delivery conduits of a vapor-phase delivery system.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

Some embodiments provide systems, apparatuses, and methods to control the temperature of precursor at various stages of supply and delivery to a process chamber including regions spanning separable portions of the process chamber and regions routed through tight spaces unable to accommodate conventional heating and insulation techniques.

Additional aspects will be set forth in the detailed description which follows, and, in part, will be apparent from the disclosure, or may be learned by practice of the disclosed embodiments and/or the claimed subject matter.

According to some embodiments, an apparatus includes a semiconductor process chamber, at least one gas distributor, a first fluidic interface assembly, and a second fluidic interface assembly. The semiconductor process chamber includes a first part and a second part moveably connected with the first part in a first configuration. The first part and the second part define an enclosure in association with the first configuration. The at least one gas distributor is configured to distribute one or more process gases in the enclosure. The first fluidic interface assembly includes a first fluidic disconnect, a first conduit extending in an axial direction and including a first end structurally connected to the first fluidic disconnect, and a first temperature-controlled enclosure at least partially encircling and in contact with the first conduit. The first temperature-controlled enclosure is structurally connected to the first part and includes a first heater. The second fluidic interface assembly is structurally connected to the second part. The second fluidic interface assembly includes a second fluidic disconnect, and a second conduit extending in the axial direction and including a first end structurally connected to the second fluidic disconnect. At least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. The first temperature-controlled enclosure is configured, by way of the first heater, to transfer thermal energy to the first conduit. The thermal energy transferred to the first conduit raises a temperature of the first conduit above a vaporization temperature of a precursor of the one or more process gases.

In some embodiments, the first fluidic passageway may be configured to supply the one or more process gases to the gas distributor.

In some embodiments, the second fluidic interface assembly may further include a second temperature-controlled enclosure at least partially encircling and in contact with the second conduit, the second temperature-controlled enclosure may be structurally connected to the second part and may include a second heater, the second temperature-controlled enclosure may be configured, by way of the second heater, to transfer thermal energy to the second conduit, and the thermal energy transferred to the second conduit may raise a temperature of the second conduit above the vaporization temperature of the precursor.

In some embodiments, the first temperature-controlled enclosure may be structurally connected to the first part within a through-hole extending through the first part.

In some embodiments, the second temperature-controlled enclosure may be structurally connected to the second part at least partially within a recessed region of the second part.

In some embodiments, the apparatus may further include a cover plate detachably coupled to the second part. The cover plate may include a surface facing the recessed region of the second part in a direction transverse to the axial direction. The surface of the cover plate may be spaced apart from the second temperature-controlled enclosure in the direction.

In some embodiments, the first fluidic interface assembly may further include a third conduit having a first end structurally connected to the first fluidic disconnect, the first temperature-controlled enclosure may at least partially encircle and may be in contact with the third conduit, and the second fluidic interface assembly may further include a fourth conduit having a first end structurally connected to the second fluidic disconnect. In the first configuration, the first fluidic disconnect and the second fluidic disconnect may be further configured to fluidically connect to form, by way of the third conduit and the fourth conduit, a second fluidic passageway spanning across the contact interface between the first part and the second part. The second fluidic passageway may be fluidically connected to a scrubbed exhaust, the first temperature-controlled enclosure may be further configured, by way of the first heater, to transfer thermal energy to the third conduit, and the thermal energy transferred to the third conduit may raise a temperature of the third conduit at least to the vaporization temperature of the precursor.

In some embodiments, the second temperature-controlled enclosure may at least partially encircle and may be in contact with the fourth conduit, the second temperature-controlled enclosure may be further configured, by way of the second heater, to transfer thermal energy to the fourth conduit, and the thermal energy transferred to the fourth conduit may raise a temperature of the fourth conduit at least to the vaporization temperature of the precursor.

In some embodiments, the apparatus may further include a third fluidic interface assembly and a fourth fluidic interface assembly. The third fluidic interface assembly may include a third fluidic disconnect structurally connected to the first part, a fifth conduit extending in the axial direction and including a first end structurally connected to the third fluidic disconnect, and a seventh conduit extending in the axial direction and including a first end structurally connected to the third fluidic disconnect. The fourth fluidic interface assembly may include a fourth fluidic disconnect structurally connected to second part, a sixth conduit extending in the axial direction and including a first end structurally connected to the fourth fluidic disconnect, and an eighth conduit extending in the axial direction and including a first end structurally connected to the fourth fluidic disconnect. In the first configuration, the third fluidic disconnect and the fourth fluidic disconnect may be configured to fluidically connect to form, by way of the fifth conduit and the sixth conduit, a third fluidic passageway spanning across the contact interface, and to form, by way of the seventh conduit and the eighth conduit, a fourth fluidic passageway spanning across the contact interface. The third fluidic passageway may be configured to supply at least one gas to the gas distributor and the fourth fluidic passageway may be configured to divert the at least one gas to a scrubbed exhaust.

In some embodiments, neither the third fluidic interface assembly nor the fourth fluidic interface assembly may include a heater, and the third fluidic interface assembly and the fourth fluidic interface assembly may be disposed adjacent to the first fluidic interface assembly and the second fluidic interface assembly.

In some embodiments, the first temperature-controlled enclosure may include a first enclosure portion and a second enclosure portion. The first enclosure portion may include a first surface, and a second surface opposing the first surface in a first direction transverse to the axial direction and facing the first conduit in a second direction opposite the first direction. The second enclosure portion may be coupled to the first enclosure portion. The second enclosure portion may include a third surface, and a fourth surface opposing the third surface in the second direction. The fourth surface may face the second surface in the first direction and may include a first channel, which may be configured to receive a portion of the first conduit therein.

In some embodiments, the first enclosure portion may include a plurality of first openings in the second surface, the second enclosure portion may include a plurality of first through-holes extending between the third surface and the fourth surface, each of the first through-holes may be respectively aligned with a corresponding first opening of the first openings, and the first temperature-controlled enclosure may further include a plurality of first fasteners. Each of the first fasteners may extend through a respective first through-hole of the first through-holes and may engage with the corresponding first opening aligned with the respective first through-hole.

In some embodiments, the third surface of the second enclosure portion may include one or more alignment features, which may be configured to interface with one or more corresponding alignment features in at least one other component of the first temperature-controlled enclosure.

In some embodiments, the first temperature-controlled enclosure may further include at least one thermocouple connected to the third surface of the second enclosure portion.

In some embodiments, the at least one thermocouple may include a first thermocouple connected to the third surface of the second enclosure portion in a position overlapping the first channel in the first direction, and a second thermocouple connected to the third surface of the second enclosure portion in a position overlapping a second channel formed in the fourth surface of the second enclosure portion. The second channel may be configured to receive a portion of a third conduit therein.

In some embodiments, the fourth surface of the second enclosure portion may include a protrusion extending in the first direction, the second enclosure portion may include a second through-hole extending from the third surface through the protrusion, the second through-hole may be configured to receive a second fastener therethrough, and the second fastener may be configured to engage with the first part to structurally connect the first temperature-controlled enclosure to the first part.

In some embodiments, the first enclosure portion may include a third through-hole extending between the first surface and the second surface, and the third through-hole may be configured to receive the protrusion in the fourth surface of the second enclosure portion therethrough.

In some embodiments, the first fluidic interface assembly may further include one or more thermal insulators, which may be configured to at least partially thermally insulate the first part from the first temperature-controlled enclosure.

In some embodiments, the one or more thermal insulators may include quartz.

In some embodiments, the one or more thermal insulators may include a first thermal insulator disposed between the first enclosure portion and a first corresponding portion of the first part.

In some embodiments, the through-hole in the first part may extend in the axial direction, the through-hole may include an opening extending in a direction transverse to the axial direction, and the first thermal insulator may abut against a first surface of the protrusion in the fourth surface of the second enclosure portion and a corresponding surface of the opening in the through-hole in the first part.

In some embodiments, the one or more thermal insulators may include a second thermal insulator disposed between the second enclosure portion and a second corresponding portion of the first part.

In some embodiments, the second thermal insulator may include a first through-hole aligned with the second through-hole in the second enclosure portion, the first through-hole in the second thermal insulator may be configured to receive the second fastener therethrough, and the second thermal insulator may include the one or more corresponding alignment features, which may be configured to interface with the one or more alignment features of the third surface of the second enclosure portion.

In some embodiments, the first enclosure portion may include a fifth surface extending between the first surface and the second surface, the second enclosure portion may include a sixth surface extending being the third surface and the fourth surface, and the first fluidic disconnect may abut against the fifth surface and the sixth surface.

In some embodiments, the first enclosure portion and the second enclosure portion may include aluminum.

In some embodiments, the second temperature-controlled enclosure may include a third enclosure portion and a fourth enclosure portion. The third enclosure portion may include a seventh surface, and an eighth surface opposing the seventh surface in a second direction transverse to the axial direction and facing the second conduit in a first direction opposite the second direction. The fourth enclosure portion may be coupled to the third enclosure portion. The third enclosure portion may include a ninth surface, and a tenth surface opposing the ninth surface in the first direction, the tenth surface facing the eighth surface in the second direction and including a second channel configured to receive a portion of the second conduit therein.

In some embodiments, the third enclosure portion may include a plurality of second openings in the eighth surface, the fourth enclosure portion may include a plurality of second through-holes extending between the ninth surface and the tenth surface, each of the second through-holes may be respectively aligned with a corresponding second opening of the second openings, and the second temperature-controlled enclosure may further include a plurality of second fasteners. Each of the second fasteners may extend through a respective second through-hole of the second through-holes and may engage with the corresponding second opening aligned with the respective second through-hole.

In some embodiments, the fourth enclosure portion may include a first chamfered surface at a first side of the ninth surface and a second chamfered surface at a second side of the ninth surface. The first chamfered surface and the second chamfered surface may extend between the ninth surface and the tenth surface. The second temperature-controlled enclosure may further include at least one thermocouple connected to one of the first chamfered surface and the second chamfered surface.

In some embodiments, the at least one thermocouple may include a third thermocouple connected to the first chamfered surface and a fourth thermocouple connected to the second chamfered surface.

In some embodiments, the tenth surface of the fourth enclosure portion may include a protrusion extending in the second direction, the fourth enclosure portion may include a fourth through-hole extending from the ninth surface through the protrusion, the fourth through-hole may be configured to receive a third fastener therethrough, and the third fastener may be configured to engage with the second part to structurally connect the second temperature-controlled enclosure to the second part.

In some embodiments, the third enclosure portion may include a fifth through-hole extending between the seventh surface and the eighth surface, and the fifth through-hole may be configured to receive the protrusion in the tenth surface of the fourth enclosure portion therethrough.

In some embodiments, the second fluidic interface assembly may further include one or more thermal insulators configured to at least partially thermally insulate the second part from the second temperature-controlled enclosure.

In some embodiments, the one or more thermal insulators may include quartz.

In some embodiments, the one or more thermal insulators may include a third thermal insulator disposed between the fourth enclosure portion and a first corresponding portion of the second part.

In some embodiments, the recessed region of the second part may include a first recessed region, a second recessed region recessed further into the second part than the first recessed region, and a resting surface extending between the first recessed region and the second recessed region. In a view transverse to the axial direction, the fourth enclosure portion may have a T-shape including a web portion extending in the axial direction and flange portions extending in directions transverse to the axial direction. The third thermal insulator may be stacked between the resisting surface of the recessed region and first surfaces of each of the protrusion in the tenth surface of the fourth enclosure portion and the flange portions of the fourth enclosure portion.

In some embodiments, the third thermal insulator may include a C-shaped configuration at least partially encircling the web portion of the fourth enclosure portion.

In some embodiments, the one or more thermal insulators may include a fourth thermal insulator disposed between the fourth enclosure portion and a second corresponding portion of the second part.

In some embodiments, the fourth thermal insulator may include a second through-hole aligned with the fourth through-hole in the fourth enclosure portion, and the second through-hole in the fourth thermal insulator may be configured to receive the third fastener therethrough.

In some embodiments, the third thermal insulator may be stacked between the fourth thermal insulator and the resisting surface extending between the first recessed region and the second recessed region of the second part.

In some embodiments, the third enclosure portion may include an eleventh surface extending between the seventh surface and the eighth surface, the fourth enclosure portion may include a twelfth surface extending being the ninth surface and the tenth surface, and the second fluidic disconnect may abut against the eleventh surface and the twelfth surface.

In some embodiments, the third enclosure portion and the fourth enclosure portion may include aluminum.

In some embodiments, the first fluidic disconnect may include a first body having a first surface, the second fluidic disconnect may include a second body having a second surface facing the first surface in the axial direction, at least one of the first body and the second body may include a first blind opening concentrically aligned with the first conduit and the second conduit, and the first blind opening may include a gasket that, in the first configuration, may be at least partially compressed between the first body and the second body and may fluidically seal the first fluidic passageway between the first body and the second body.

In some embodiments, the at least one of the first body and the second body may further include a second blind opening concentrically aligned with the third conduit and the fourth conduit, and the second blind opening may include a gasket that, in the first configuration, may be at least partially compressed between the first body and the second body and may fluidically seal the second fluidic passageway between the first body and the second body.

In some embodiments, the at least one of the first body and the second body may further include one or more leak detection grooves fluidically connected to the first blind opening and the second blind opening.

In some embodiments, a second end of the first conduit may be fluidically connected to the gas distributor, and a second end of the second conduit may be fluidically connected to a source of the precursor.

In some embodiments, the first part may form a lid of the semiconductor process chamber.

In some embodiments, the first part and the second part may include aluminum.

In some embodiments, a source of the precursor may be an intermediary source, which may be configured to maintain the precursor in a liquid-phase during storage.

In some embodiments, the intermediary source may include a vaporizer, which may be configured to flow the precursor into the first fluidic passageway as a vapor.

In some embodiments, the intermediary source may be positioned at a lower elevation than the semiconductor process chamber.

In some embodiments, the intermediary source may be fluidically connected to a centralized source of the precursor, and the intermediary source may be further configured to replenish a supply of the precursor from the centralized supply.

In some embodiments, the centralized source may be positioned at a lower elevation than the intermediary source.

In some embodiments, the intermediary source may be supported on a floor of a fabrication facility, and the centralized source may be supported below the floor of the fabrication facility.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIGS. 1 and 2 schematically illustrate a semiconductor processing system, which may not only be used to process a semiconductor wafer, but may also be capable of thermally controlling a disconnect according to some embodiments.

FIG. 3 schematically illustrates a process chamber according to some embodiments.

FIG. 4 schematically illustrates a portion of a fluid delivery network of the semiconductor processing system of FIGS. 1 and 2 according to some embodiments.

FIG. 5 schematically illustrates a partially exploded perspective view of a portion of a process chamber including a thermally controlled disconnect according to some embodiments.

FIGS. 6 and 7 schematically illustrate first and second orthographic detail views of portions of the process chamber of FIG. 5 according to some embodiments.

FIG. 8 schematically illustrates a partial section view of the process chamber of FIG. 5 according to some embodiments.

FIGS. 9 and 10 schematically illustrate partial perspective and orthographic views of a first part of the process chamber of FIG. 5 according to some embodiments.

FIGS. 11 and 12 schematically illustrate partial perspective and orthographic views of a second part of the process chamber of FIG. 5 according to some embodiments.

FIGS. 13 and 14 schematically illustrate perspective views of the thermally controlled disconnect of FIG. 5 according to some embodiments.

FIG. 15 schematically illustrates an exploded perspective view of a first fluidic interface assembly of the thermally controlled disconnect of FIG. 5 according to some embodiments.

FIG. 16 schematically illustrates an exploded perspective view of a second fluidic interface assembly of the thermally controlled disconnect of FIG. 5 according to some embodiments.

FIGS. 17-21 schematically illustrate various views of a first enclosure portion of the first fluidic interface assembly of FIG. 15 according to some embodiments.

FIG. 22 schematically illustrates a perspective view of a second enclosure portion of the first fluidic interface assembly of FIG. 15 according to some embodiments.

FIGS. 23 and 24 schematically illustrate various views of a second thermal insulator of the first fluidic interface assembly of FIG. 15 according to some embodiments.

FIG. 25 schematically illustrates a perspective view of a first thermal insulator of the first fluidic interface assembly of FIG. 15 according to some embodiments.

FIGS. 26 and 27 schematically illustrate perspective and orthographic views of a first fluid disconnect of the first fluidic interface assembly of FIG. 15 according to some embodiments.

FIGS. 28-32 schematically illustrate various views of a fourth enclosure portion of the second fluidic interface assembly of FIG. 16 according to some embodiments.

FIG. 33 schematically illustrates a perspective view of a third enclosure portion of the second fluidic interface assembly of FIG. 16 according to some embodiments.

FIG. 34 schematically illustrates a perspective view of a third thermal insulator of the second fluidic interface assembly of FIG. 16 according to some embodiments.

FIG. 35 schematically illustrates a partial perspective view of a cartridge heater of at least one of first and second fluidic interface assemblies of FIGS. 15 and 16 according to some embodiments.

FIGS. 36 and 37 schematically illustrate perspective and orthographic views of a second fluid disconnect of the second fluidic interface assembly of FIG. 16 according to some embodiments.

FIGS. 38 and 39 schematically illustrate perspective views of third and fourth fluidic disconnects of the process chamber of FIG. 5 according to some embodiments.

FIG. 40 schematically illustrates a multi-station processing tool according to some embodiments.

### DETAILED DESCRIPTION OF SOME EMBODIMENTS

In the following description, numerous specific details are set forth in order to provide a thorough understanding of various embodiments. The disclosed embodiments may be practiced without some or all of these specific details. In other instances, well-known process operations have not been described in detail to not unnecessarily obscure the disclosed embodiments. While the disclosed embodiments will be described in conjunction with specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles, such as printed circuit boards, magnetic recording media, magnetic recording sensors, mirrors, optical elements, micro-mechanical devices, and the like.

### Context

As previously mentioned, various semiconductor manufacturing processes (such as atomic layer deposition (ALD), atomic layer etching (ALE), chemical vapor deposition (CVD), chemical vapor etching (CVE), and the like, as well as plasma-enhanced versions of the same) may employ at least one vapor-phase delivery system in which vapor-phase and sometimes gas precursors are reacted with and/or on a surface of a substrate to deposit material thereon or remove material therefrom. Although many forms of vapor-phase delivery systems exist, they are usually configured to provide controlled gas flow, vaporization, and delivery of precursors, which may otherwise be in a liquid-or solid-phase at ambient temperature and atmospheric pressure conditions. Although the transition from a solid-phase directly to a gaseous-phase is technically a sublimation process, as used herein, terms like “vaporization” are used to refer to the transition from a solid-or liquid-phase to a gaseous-phase. The difference in phases between storage and supply of a precursor presents numerous challenges thwarting efforts to prevent undesired condensation, deposition, etching, particle generation, etc., in and/or from at least the delivery conduits of a vapor-phase delivery system.

For instance, vapor-phase delivery systems commonly use an evaporator, such as a heating vessel, to transition a precursor from a liquid-or solid-phase into a vapor-phase. As part of processing a substrate, the vapor-phase precursor may flow into a process volume through one or more delivery conduits, which are typically heated at one or more points. For example, some portions of the delivery conduits may be heated using at least one of a flexible polymeric heating jacket having one or more resistive heating elements or via heating tape. In some cases, wrap insulation may be utilized to cover the heating tape and/or jacket to reduce thermal losses. Although the injection of thermal energy to and insulation of the delivery conduits may help prevent condensation, deposition, etc., of the vapor-phase precursor in the delivery conduits, some portions of the delivery conduits may be routed through tight spaces unable to accommodate conventional heating and insulation techniques. In some cases, these spaces may be (or may be adjacent to spaces that are) sensitive to extraneous heat.

Moreover, the structural configuration and separability of components defining some process chambers, as well as the purging of process gases between stages of deposition and/or etching further exacerbate the above-noted issues. For example, some process chambers may include a moveable top portion that can be lifted away from a lower chamber portion to allow access to interior spaces. As such, flow paths of a vapor-phase delivery system spanning at least the separable portions of the process chamber typically allow for disconnection without human intervention and may include one or more flexible conduits to account for different relative positions between the process chamber components. In addition, the flow paths may be double contained, e.g., the flow paths may include a medium carrying inner conduit and at least one containment outer conduit enclosing the inner conduit to protect against unexpected leakage from the inner conduit. It is noted, however, that these disconnects are usually routed through the aforementioned tight spaces that are typically not accommodative to conventional heating and insulation techniques. Such configurations give rise to temperature differentials that create conditions allowing for undesired condensation, deposition, etching, particle generation, etc., in and/or from the delivery conduits of a vapor-phase delivery system. It is also noted that the disconnects are typically in contact with at least one of the moveable top portion and the lower chamber portion. Heating these disconnects can lead to undesired heat transfer to the process chamber and cause, at least in part, potential sources of variability in process conditions and/or product structures, performance, etc.

Some semiconductor manufacturing tools may employ precursor supplies (such as ampoules filled with different chemistries) that are mounted above the split plane of the moveable process chamber components to eliminate the above-noted disconnects. It is noted, however, that once the resources within the ampoules are expended, the ampules are either discarded and replaced with new ampoules (thereby creating increased waste) or refilled. In either case, replenishing the precursor supplies leads to downtime and increased costs in supporting various ampoules and associated semiconductor manufacturing tools. Accordingly, various embodiments are directed towards providing effective, cost-efficient temperature control techniques and devices to control the temperature of precursor at various stages of supply and delivery to a process chamber including in regions spanning separable portions of a process chamber and regions routed through tight spaces that are otherwise unable to accommodate conventional heating and insulation techniques.

### Systems for Semiconductor Processing

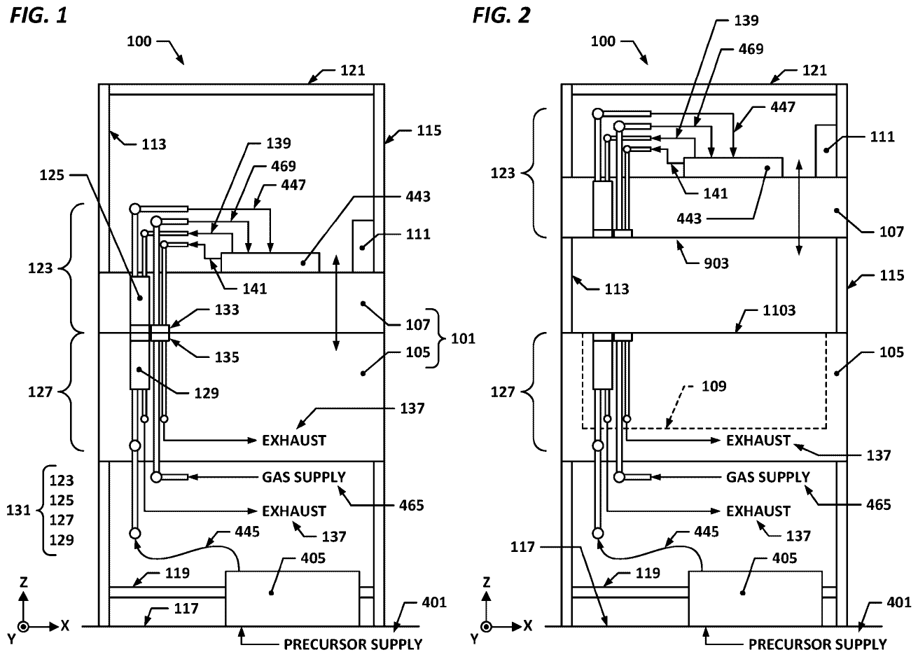

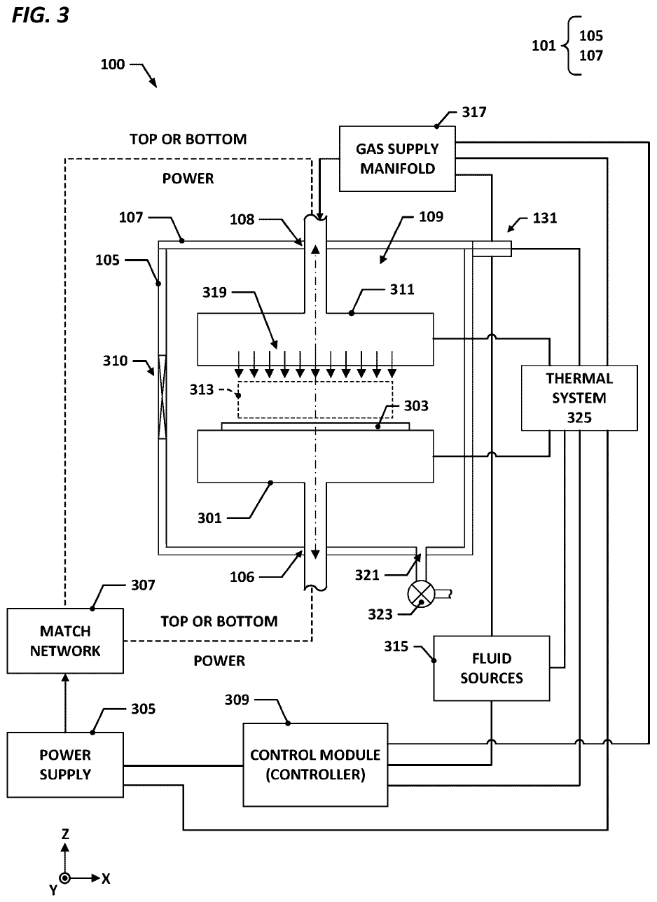

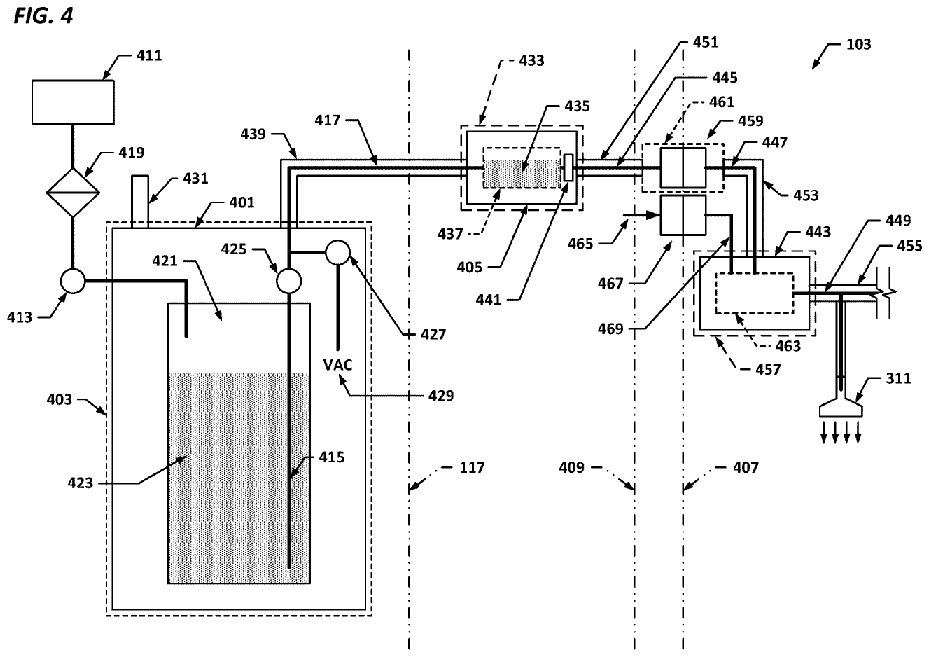

FIGS. 1 and 2 schematically illustrate a semiconductor processing system, which may not only be used to process a semiconductor wafer, but may also be capable of thermally controlling a disconnect according to some embodiments. FIG. 3 schematically illustrates a process chamber of the semiconductor processing system of FIGS. 1 and 2 according to some embodiments. FIG. 4 schematically illustrates a portion of a fluid delivery network of the semiconductor processing system of FIGS. 1 and 2 according to some embodiments.

Referring to FIGS. 1-4, semiconductor processing system (or system) 100 may include process chamber 101 fluidically connected to fluid delivery network (or system) 103. Process chamber 101 may include first part 105 and second part 107 moveably connected with first part 105. In some embodiments, first part 105 may define a lower portion (or module) of process chamber 101 in which at least one internal cavity region 109 may be formed and second part 107 may define an upper (or lid) portion of process chamber 101. At least one of first and second parts 105 and 107 may be configured to translate in (or along) an axial direction, e.g., a direction parallel (or substantially parallel) to the Z-axis depicted in FIGS. 1 and 2. This may allow access to at least internal cavity region 109 of process chamber 101. As shown in FIGS. 1 and 2, at least one actuator (e.g., actuator 111) may be used to cause, at least in part, second part 107 to be displaced in the axial direction along a plurality of support rails (e.g., support rails 113 and 115) of a support structure (or frame). In some cases, actuator 111 may be any suitable mechanism capable of inducing linear motion, such as a stepper motor, servomotor, etc., that is coupled to at least one of process chamber 101 and the support structure, but embodiments are not limited thereto. For instance, second part 107 may, in some implementations, be lifted away from first part 105 via an integrated or detachable tool lift, hoist, robotic arm, etc. Further, the support structure may be configured to support process chamber 101 in an elevated position from floor 117 of, for example, a fabrication facility. As such, the support rails (such as support rails 113 and 115) of the support structure may be laterally reinforced via one or more lateral and/or cross braces, such as lateral braces 119 and 121.

Adverting momentarily to FIG. 3, some additional features of process chamber (or chamber) 101 will now be described. As mentioned, chamber 101 may be divided into first part 105 and second part 107 moveably connected to first part 105. In a first position, state, or configuration, such as illustrated in FIGS. 1 and 3, first and second parts 105 and 107 may be connected together to enclose a space at least partially defined by internal cavity region 109. In a second position, state, or configuration, such as illustrated in FIG. 2, second part 107 may be lifted away from first part 105 to allow access to at least internal cavity region 109. A center column may be configured to support pedestal 301 within internal cavity region 109 when, for example, a surface of wafer 303 is being processed, e.g., when a film is being formed on a surface of wafer 303, a feature is being etched in the surface of wafer 303 or a structure formed on the surface of wafer 303, etc.

In accordance with some embodiments, pedestal 301 may be or include a powered electrode. As such, pedestal 301 may be electrically coupled to power supply 305 via match network 307. To this end, power supply 305 may be controlled by control module (or controller) 309. In some implementations, power may be provided to gas distributor 311 instead of (or in addition to) pedestal 301. Control module 309 may be configured to operate aspects of system 100 by executing one or more sequences of one or more instructions defining at least one process recipe. As such, control module 309 may set various operational inputs for defining a process recipe, such as power levels, pressurization levels, timing parameters, process gases, precursor supply, mechanical movement of wafer 303, height of wafer 303 from pedestal 301, thermal control of one or more components of chamber 101, such as thermally controlled disconnect 131, etc.

According to some embodiments, the center column may include a lift pin mechanism communicatively coupled to lift pins. The lift pin mechanism and, thereby, the lift pins may be controlled by a lift pin control signal from, for instance, control module 309. The lift pins may be used to raise wafer 303 from pedestal 301 to allow an end-effector to pick wafer 303 and to lower wafer 303 after being placed by the end end-effector. In some embodiments, the lift pins may be part of the center column. To this end, chamber 101 may include chamber transport port 310 through which the end-effector may introduce or remove wafer 303 from chamber 101. In some cases, relative displacement between pedestal 301 and gas distributor 311 may be utilized to provide a controlled separation of wafer 303 from a surface of gas distributor 311 facing wafer 303. The controlled separation of wafer 303 from a surface of gas distributor 311 may also be configured to control a size of process volume 313 in which at least vapor-phase precursor may be distributed via gas distributor 311. Chamber 101 may also include openings 106 and 108 through which portions of pedestal 301 and gas distributor 311 extend, such as stem portions of pedestal 301 and gas distributor 311. Although gas distributor 311 is shown with a showerhead configuration, embodiments are not limited thereto. For instance, gas distributor 311 may be formed as a top plate, and thereby, incorporated as a portion of second part 107 of chamber 101. Any other suitable form of gas distributor may be utilized; however, for convenience, gas distributor 311 will be described having a showerhead configuration.

System 300 may further include one or more fluid sources 315, e.g., gas chemistry supplies from a facility and/or purge (e.g., inert) gases. Depending on the process(es) being performed, control module 309 may control the delivery of one or more gases from fluid sources 315 as will become more apparent below. The one or more gases may be distributed at least within process volume 313 via gas distributor 311. In some embodiments, gas manifold 317 may be fluidically interposed between fluid sources 315 and gas distributor 311. Appropriate valving and mass flow control mechanisms may be employed and controlled via control module 309 to ensure suitable gases are delivered during, for example, deposition, etching, and/or plasma treatment phases of a process. To this end, the flow of gases may be provided to gas manifold 317 via thermally controlled disconnect 131 as will become more apparent below. In this manner, gas may flow into gas distributor 311 from gas supply manifold 317 and output from gas distributor 311 as gas flow 319. Gas flow 319 may be distributed in region (or process volume) 313, which may be formed between wafer 303 and a respective surface of gas distributor 311. Although illustrated as a rectangular area, region 313 may be more of a nebulous cloud-like region in which, for instance, plasma may be generated and/or one or more process gases, purge gases, or both process and purge gases may flow. In some cases, gas flow 319 may include one or more vapor-phase precursors exhibiting a solid-or liquid-phase at ambient temperature and pressure conditions of a fabrication facility. The delivery of one or more process gases, purge gases, or both process and purge gases will now be described in more detail in association with FIGS. 1, 2, and 4.

Referring to FIGS. 1, 2, and 4, vapor delivery network (or system) 103 may be configured to supply one or more vapor-phase precursors to at least one gas distributor, such as gas distributor 311, by vaporizing a precursor that exhibits a liquid-or solid-phase at ambient temperature and pressure conditions. For convenience, the liquid-or solid-phase precursor will, hereinafter, be referred to as a precursor or a solid-phase precursor, but should be understood to also include liquid-phase precursor embodiments. In some implementations, the solid-phase precursor may be stored in bulk storage (or tank) 401, which may include one or more heaters (e.g., heater 403) configured to transition and/or maintain the solid-phase precursor in a liquid-phase for delivery to intermediate source (or supply) 405. In some cases, heater 403 may be configured to heat the precursor to a first temperature or within a first temperature range T1. It is noted that bulk storage 401 may also be referred to as a centralized source of one or more precursors and may be fluidically connected to one or more intermediate sources associated with one or more semiconductor process tools (or modules), such as process chamber 101 or stations of multi-station tool 4000.

According to some embodiments, bulk storage 401 may be positioned at a lower elevation than at least one of process chamber 101 and intermediate source 405. For example, bulk storage 401 may be positioned and/or supported below floor 117 of, for instance, a fabrication facility and intermediate source 405 may be supported on or above floor 117. In some cases, intermediate source 405 may be positioned below split plane 407 of process chamber 101 or below plane 409, which may represent a plane at least tangent to a lowermost surface of second part 107 of process chamber 101. It is noted that split plane 407 may represent a plane at least tangent to at least one contact interface between first and second parts 105 and 107 of process chamber 101.

Push gas source 411 may be configured to supply one or more push gases (such as one or more inert gases, e.g., argon, helium, neon, nitrogen, and/or the like) to at least bulk storage 401 via valve 413 to force or otherwise facilitate flow of liquid-phase precursor to intermediate source 405 via one or more delivery conduits, such as delivery conduits 415 and 417. For the purposes of this disclosure, an inert gas may be a gas that is non-reactive with the precursor(s) and/or counter-reactant(s) of an associated semiconductor process. In some cases, gas purifier 419 may be fluidically interposed between push gas source 411 and bulk storage 401. Gas purifier 419 may be configured to remove contaminates, such as oxygen, moisture, hydrocarbons, etc., from a flow of push gas between push gas source 411 and bulk storage 401. In this manner, gas purifier 419 may include any suitable number of traps, filters, catalytic materials, indicators, sensors, etc., to prevent or at least reduce the diffusion of actual and/or potential contaminants into the push gas stream and maintain gas purity levels. As part of operation, push gas may be supplied to vapor space 421 of bulk storage 401 via valve 413 to cause, at least in part, some of liquid-phase precursor 423 to flow out of bulk storage 401 and into intermediate source 405.

Flow of liquid-phase precursor to intermediate source 405 may also be controlled or otherwise facilitated via actuation of one or more other valves (such as valves 425 and 427), pumps, etc. Whereas valve 413 may provide an inlet gatekeeping function capable of controlling the flow of push gas into bulk storage 401, valve 425 may provide an outlet control function that regulates the flow of liquid-phase precursor from bulk storage 401. It is also noted that valve 427 may be utilized to selectively and fluidically connect delivery conduit 417 to vacuum 429, which may be utilized to purge delivery conduit 417 before and/or after supply of liquid-phase precursor to intermediate source 405. Bulk storage 401 may also include exhaust (or vent) 431 to prevent the build-up of excessive pressure and/or vacuum accumulation in vapor space 421 that might otherwise be caused by, for instance, changes in liquid-precursor levels, variations in ambient temperature conditions, heating of bulk storage 401, etc.

According to some embodiments, intermediate source 405 may be heated via one or more heaters (e.g., heater 433) to maintain intermediate supply 435 of precursor in a liquid-phase. In some cases, heater 433 may be configured to heat intermediate supply 435 to a second temperature or within a second temperature range T2. Second temperature (or temperature range) T2 may be greater than first temperature (or temperature range) T1, but embodiments are not limited thereto. In some cases, storage space 437 of intermediate source 405 may be pressurized with inert gas, which may be the same as or different from the push gas of push gas source 411. It is also noted that delivery conduit 417 between bulk storage 401 and intermediate source 405 may be heated via, for instance, heating jacket 439 (such as a flexible polymeric heating jacket) to maintain the liquid-phase of precursor flowing therein, but embodiments are not limited thereto. Heating jacket 439 may be configured to heat the liquid-phase precursor to a third temperature or within a third temperature range T3. Third temperature (or temperature range) T3 may be greater than or equal to first temperature (or temperature range) T1 and less than or equal to second temperature (or temperature range) T2, but embodiments are not limited thereto.

In some implementations, a flow controller (such as a liquid flow controller) of or associated with intermediate source 405 may be utilized to regulate the flow (e.g., mass flow) of liquid-phase precursor from bulk storage 401 to intermediate source 405 and from storage space 437 to vaporizer (or evaporator) 441. Although vaporizer 441 is shown as being part of intermediate source 405, embodiments are not limited thereto. It is also noted that the flow controller may be configured to control the operation of one or more of push gas source 411, valves 413, 425, and 427, and/or vaporizer (or vaporization point) 441. To this end, the flow controller may be configured to receive feedback information (such as at least one of temperature, pressure, volumetric flow, etc., feedback information) from one or more sensors positioned in and/or along various points of bulk storage 401, delivery conduit 417, storage space 437, and/or vaporizer 441. This feedback information may be utilized to regulate the flow of liquid-phase precursor from bulk storage 401 to intermediate source 405 and from storage space 437 to vaporizer 441. In some cases, the flow controller may be configured to draw and/or replenish intermediate supply 435 using precursor from bulk storage 401 in any suitable fashion, such as in an on-demand, scheduled, and/or randomized manner, and/or based on any suitable information, such as supply level information related to an amount of intermediate supply 435 in storage space 437.

Vaporizer 441 may be configured to transition at least some of the precursor corresponding to intermediate supply 435 into a vapor-phase or gaseous state for supply to gas distributor 111 of process chamber 101. In some embodiments, vaporizer 441 may be a heated vaporizer. For instance, one or more surfaces of vaporizer 441 may be heated to a fourth temperature or within a fourth temperature range T4 that is above the vaporization temperature of the precursor being utilized. Fourth temperature (or temperature range) T4 may, therefore, be greater than second temperature (or temperature range) T2. As such, vapor-phase precursor may be delivered to gas manifold 443 via delivery conduits 445 and 447. To prevent or at least reduce the likelihood that the vapor-phase precursor output from vaporizer 441 condenses and potentially reacts with incompatible gases or materials in downstream components, at least delivery conduits 445, 447, and 449 may be heat traced above the vaporization temperature of the precursor flowing therethrough. In some implementations, heating jackets 451, 453, and 455 may be utilized to respectively control the temperature of and/or within delivery conduits 445, 447, and 449, but embodiments are not limited thereto. In some implementations, heating jackets 451, 453, and 455 may be configured to at least heat delivery conduits 445, 447, and 449 to fifth, sixth, and seventh temperatures or within fifth, sixth, and seventh temperature ranges T5, T6, and T7, respectively. In some embodiments, fifth temperature (or temperature range) T5 may be greater than fourth temperature (or temperature range) T4, sixth temperature (or temperature range) T6 may be greater than fifth temperature (or temperature range) T5, and seventh temperature (or temperature range) T7 may be greater than sixth temperature (or temperature range) T6. It is also contemplated that the temperature of gas manifold 443 may be controlled via one or more heaters, such as heater 457. Heater 457 may be configured to at least heat gas manifold 443 to an eighth temperature or within an eighth temperature range T8, which may be between sixth temperature (or temperature range) T6 and seventh temperature (or temperature range) T7.

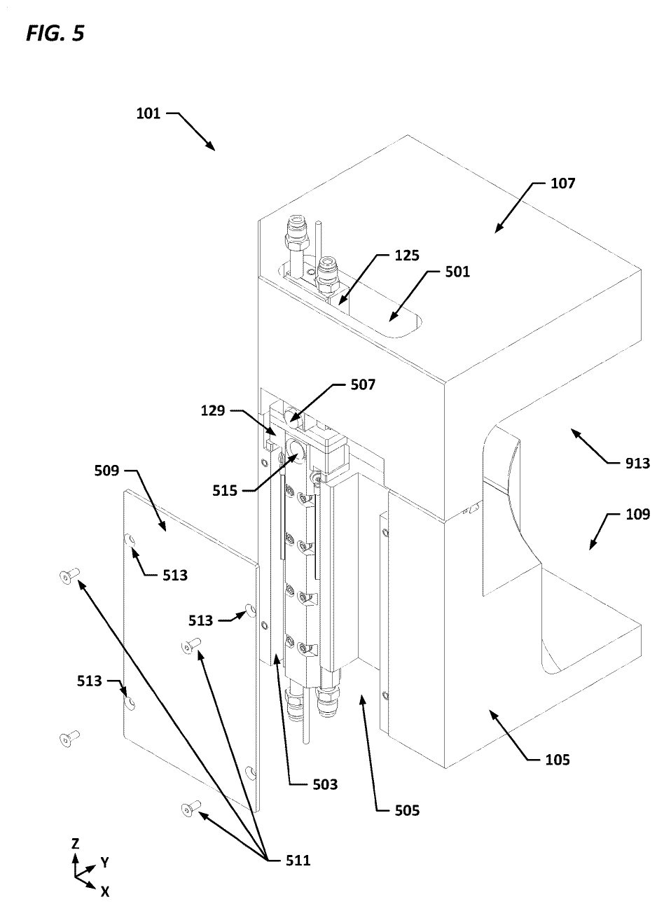

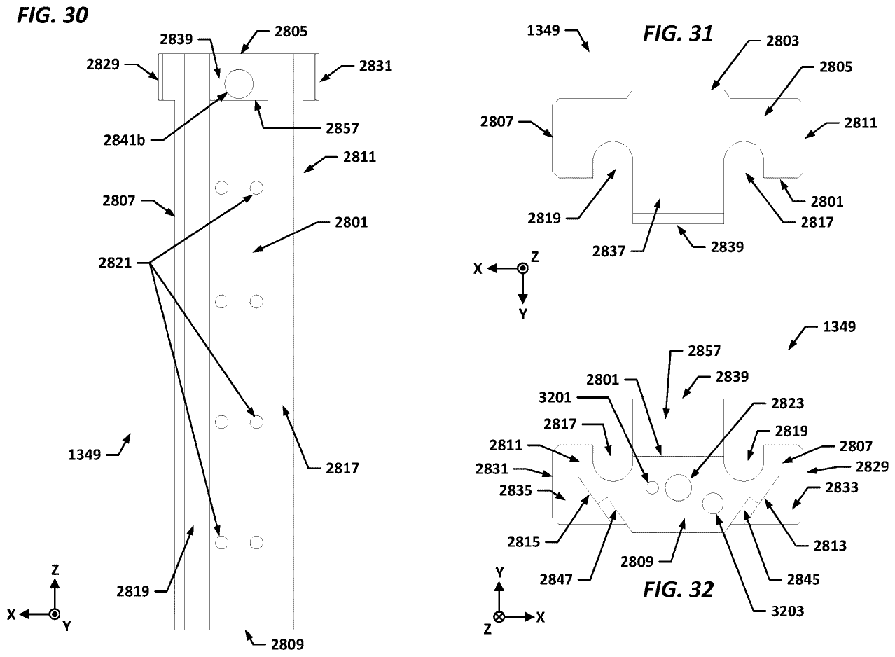

According to various embodiments, delivery conduits 445 and 447 may be respectively connected to one or more delivery conduits and disconnects (collectively identified as fluidic interface assemblies 459) that are routed through one or more tight spaces of (or adjacent to) first and/or second parts 105 and 107 of process chamber 101. These spaces may be unable to accommodate typical heating and insulation techniques. As such, the temperature of fluidic interface assemblies 459 may be regulated (such as controlled to be above the vaporization temperature of the precursor flowing therethrough) via one or more temperature-controlled enclosures, which are collectively identified as temperature-controlled enclosures 461 in FIG. 4. A temperature-controlled enclosure may be, or include, for example, a sleeve, a raceway, or an enclosed channel through which one or more conduits may pass. In some cases, fluidic interface assemblies 459 may include first fluidic interface assembly 123 having first temperature-controlled enclosure 125 and second fluidic interface assembly 127 having second temperature-controlled enclosure 129. The combination of first and second fluidic interface assemblies 123 and 127 having at least one of first and second temperature-controlled enclosures 125 and 129 may be considered a thermally controlled disconnect, which is identified as call reference number 131. Example fluidic interface assemblies and illustrative temperature-controlled enclosures will be described in more detail in association with FIGS. 5-37, along with some areas in which the fluidic interface assemblies and temperature-controlled enclosures may be routed and/or positioned.

Before discussing examples of fluidic interface assemblies 459 and temperature-controlled enclosures 461, it is noted that the vapor-phase precursor may flow from vaporizer 441 to gas manifold 443, which may include at least one charge volume (or plenum) 463. The vapor-phase precursor received in plenum 463 may, in some cases, be diluted or otherwise mixed with one or more controlled-flows of gases 465, which may be supplied to plenum 463 via, for example, one or more delivery conduits and disconnects, collectively identified as fluidic interface assemblies 467 in FIG. 4. Gases 465 may be, in some implementations, one or more inert gases and/or one or more other types of process gases that, in some implementations, exhibit a gaseous state at ambient temperature and pressure conditions. Similar to fluidic interface assemblies 459, fluidic interface assemblies 467 may span split plane 407 of process chamber 101. That being said, fluidic interface assemblies 467 may not be temperature-controlled, but embodiments are not limited thereto. For instance, each of fluidic interface assemblies 459 and 467 may be temperature-controlled; however, to provide contrast between temperature-controlled and not temperature-controlled variants, fluidic interface assemblies 467 will be assumed and described as having not temperature-controlled configurations. In some implementations, fluidic interface assemblies 467 may include third fluidic interface assembly 133 and fourth fluidic interface assembly 135.

According to some embodiments, gas manifold 443 may be configured to flow process gas (which may include at least some of the precursor in a vapor-phase) from plenum 463 to gas distributor 311. Gas distributor 311 may be configured to distribute the process gas(es) in process volume (or region) 313, and thereby, toward wafer 303 in association with at least one semiconductor process. As seen in FIG. 3, wafer 303 may be located beneath gas distributor 311 and, in some cases, may be supported via pedestal 301. Gas distributor 311 may not only have any suitable shape, but may also have any suitable number and arrangement of gas distribution ports configured to distribute the process gas(es) to process volume 313.

In various implementations, process and/or purge gases may exit process chamber 101 via exhaust gas port (or outlet) 321 fluidically coupled to, for instance, vacuum pump 323, which may be a one or two stage mechanical dry pump and/or a turbomolecular pump. In this manner, process and/or purge gases may be drawn out of process chamber 101 to maintain a suitably low-pressure environment therein. To this end, a closed-loop flow restriction device, such as a throttle valve or a pendulum valve, may be controlled via control module 309 to further ensure a suitably low-pressure environment in process chamber 101. In some cases, fluid within delivery conduit 447 may be evacuated to, for instance, exhaust 137 via divert flow path 139, which may include one or more conduits forming portions of fluidic interface assemblies 459. Exhaust 137 may be a scrubbed exhaust. In some cases, the temperature of the one or more conduits of divert flow path 139 may be controlled via temperature-controlled enclosures 461, as will become more apparent below. This may prevent or at least reduce the likelihood of undesired condensation, deposition, etching, particle generation, etc., occurring in and/or from divert flow path 139 and components forming exhaust 137. Fluid within delivery conduit 469 may be evacuated to, for instance, exhaust 137 via divert flow path 141, which may include one or more conduits forming portions of fluidic interface assemblies 467, as will become more apparent below. The one or more conduits of divert flow path 141 may not be temperature-controlled, but embodiments are not limited thereto.

According to some embodiments, process chamber 101 may also include one or more liners (or shrouds) lining one or more interior surfaces of process chamber 101. The liner(s) may be formed of a metal or metal alloy, such as aluminum or an aluminum alloy, but embodiments are not limited thereto. The liner(s) may be configured to be removed during servicing of process chamber 101 to prevent (or at least reduce) build-up of material, e.g., metallic material, on the walls of process chamber 101. In some cases, process chamber 101 may be caused, at least in part, to be arranged in the second configuration, such as shown in FIG. 2, to allow access to internal cavity region 109 to remove, replace, and/or clean the liner(s). Further, the one or more liners may also be configured to reduce heat transfer to and from the walls of process chamber 101 to help stabilize an internal temperature of process chamber 101. Moreover, the liner(s) may serve as sacrificial layers configured to prevent (or reduce) damage to process chamber 101.

In various implementations, system 300 may include or communicate with thermal system 325, which may be configured to actively control the temperature of one or more of pedestal 301, gas distributor 311, and thermally controlled disconnect 131. In some cases, thermal system 325 may also be configured to actively control the temperature of one or more of gas supply manifold 317, fluid sources 315, and heaters 403, 433, 439, 451, 453, and 455.

For instance, thermal system 325 may be configured to control one or more aspects associated with one or more thermal control elements, e.g., heating element(s), cooling conduit(s), and/or the like, of pedestal 301, gas distributor 311, thermally controlled disconnect 131, gas supply manifold 317, fluid sources 315, and heaters 403, 433, 439, 451, 453, and 455. In some implementations, control module 309 may control the operation of thermal system 325, but embodiments are not limited thereto.

Additional aspects of process chamber 101 and thermally controlled disconnect 131 will now be discussed in more detail in association with FIGS. 1-12.

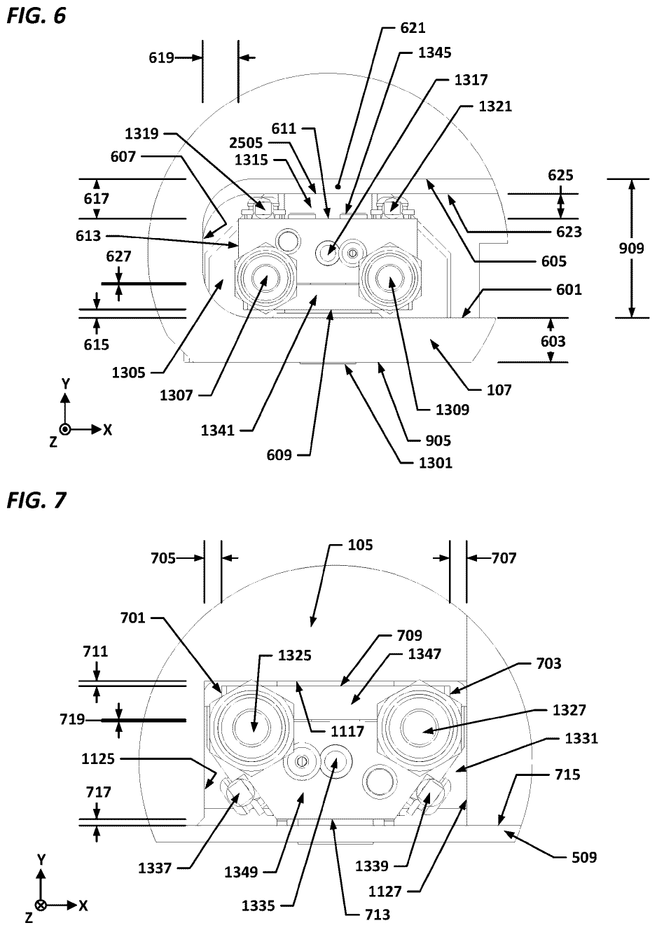

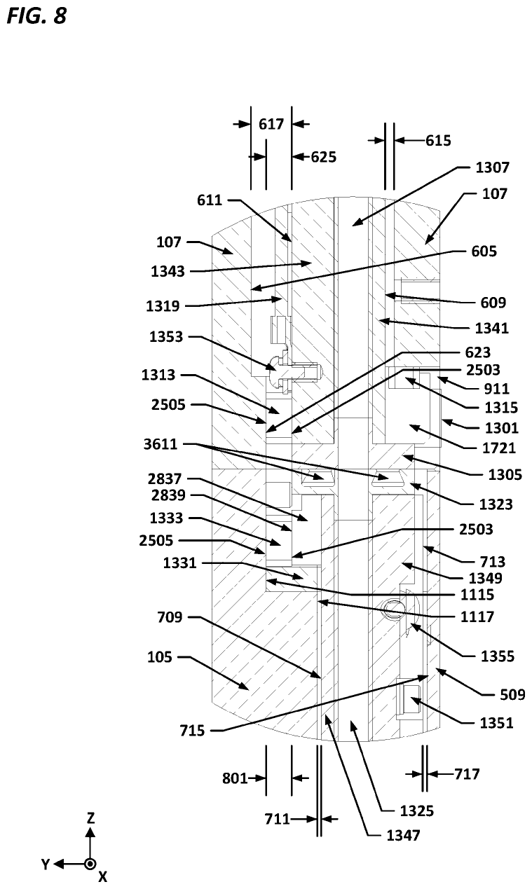

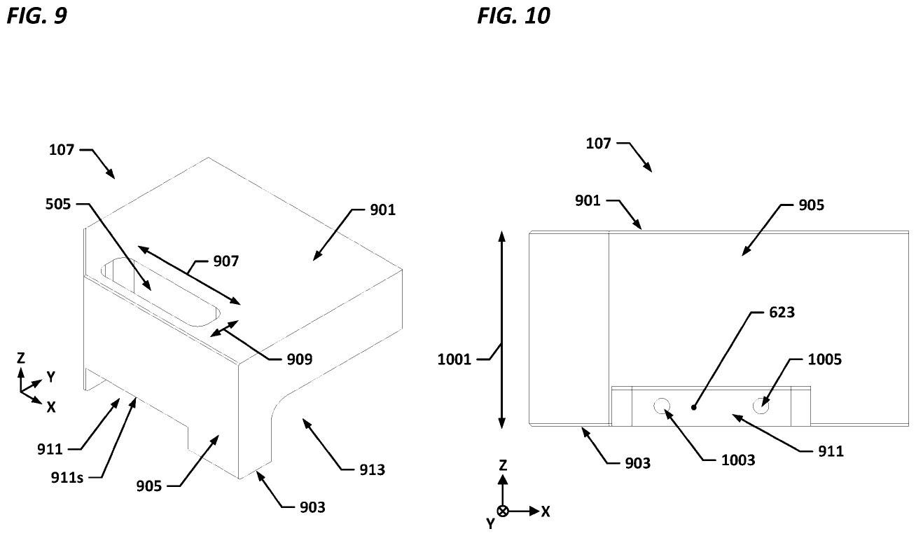

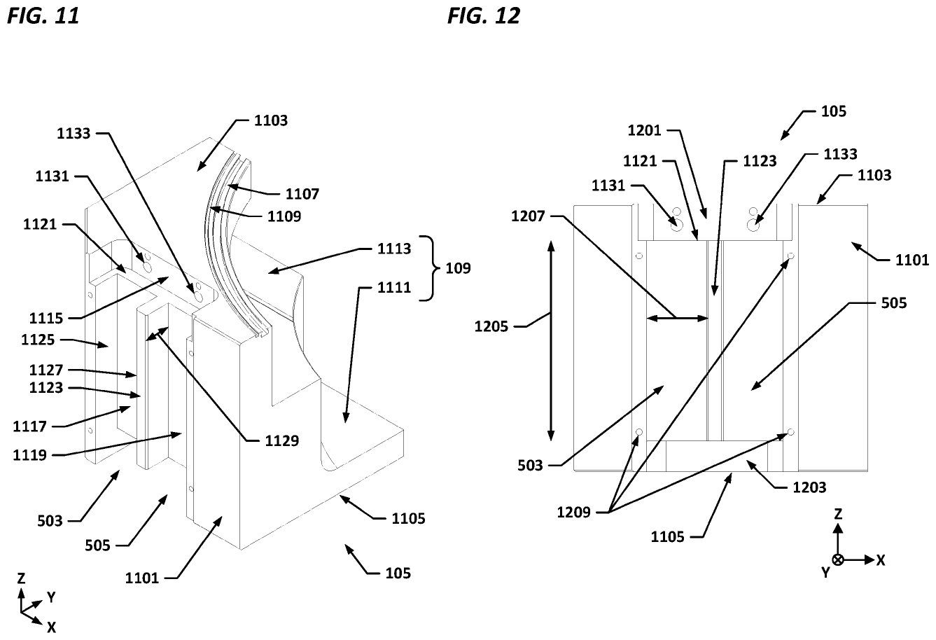

FIG. 5 schematically illustrates a partially exploded perspective view of a portion of a process chamber including a thermally controlled disconnect according to some embodiments. FIGS. 6 and 7 schematically illustrate first and second orthographic detail views of portions of the process chamber of FIG. 5 according to some embodiments. FIG. 8 schematically illustrates a partial section view of the process chamber of FIG. 5 according to some embodiments. FIGS. 9 and 10 schematically illustrate partial perspective and orthographic views of a first part of the process chamber of FIG. 5 according to some embodiments. FIGS. 11 and 12 schematically illustrate partial perspective and orthographic views of a second part of the process chamber of FIG. 5 according to some embodiments.

Referring to FIGS. 1-12, process chamber 101 may include first part 105 and second part 107 moveably connected with first part 105 in a first configuration (such as shown in FIGS. 1, 5, and 8), and capable of being spaced apart from one another in a second configuration (such as depicted in FIG. 2). For the purposes of this disclosure, “moveably connected” may include a tangent or coincident mating (or abutment) between two or more components with mutually complementing shapes enabling a physical interface between the two or more components that may be connected/unconnected when, for example, at least one of the two or more components is displaced relative to the other component(s). For example, some process chambers may include a moveable top portion that can be lifted away from a lower chamber portion to allow access to interior spaces. Given this ability to separate first and second parts 105 and 107 from one another, process chamber 101 may include one or more fluidic interface assemblies, such as fluidic interface assemblies 459 and 467, that allow flow paths of vapor-phase delivery system 103 spanning at least split plane 407 of process chamber 101 to connect and disconnect from one another. At least some of the fluidic interface assemblies, such as first and second fluidic interface assemblies 123 and 127, may be thermally controlled (e.g., heated) via, for instance, one or more temperature-controlled enclosures (e.g., first and second temperature-controlled enclosures 125 and 129) to prevent or at least reduce the likelihood of undesired condensation, deposition, etching, particle generation, etc., occurring in and/or from the flow paths associated therewith.

According to some embodiments, the fluidic interface assemblies (such as first to fourth fluidic interface assemblies 123, 127, 133, and 135), may be routed through one or more tight spaces of or associated with process chamber 101 (such as in region 501 in second part 107 and at least one of regions 503 and 505 in first part 105) that may be unable to accommodate conventional heating and insulation techniques. For example, first and third fluidic interface assemblies 123 and 133 may be routed through region 501 in second part 107. Region 501 may be a through-hole extending in an axial direction, e.g., a direction parallel or substantially parallel to the Z-axis direction, from first (e.g., upper) surface 901 of second part 107 through second (e.g., lower) surface 903 of second part 107. At least one peripheral surface, such as peripheral (e.g., front) surface 905 may extend between first and second surfaces 901 and 903. In some cases, first interior surface 601 of region 501 may be offset from peripheral surface 905 in a first direction by distance 603. The first direction may be transverse to the axial direction, and in some cases, may be parallel or substantially parallel to the Y-axis direction. Region 501 may have dimensions 907, 909, and 1001 in the axial direction, the first direction, and a second direction. The second direction may also be transverse to the axial direction, and in some implementations, may be parallel or substantially parallel to the X-axis direction.

As will become more apparent below, when first fluidic interface assembly 123 is assembled as part of second part 107 of process chamber 101, various exterior surfaces of first temperature-controlled enclosure 125 may be offset from corresponding interior surfaces of region 501, such as first, second, and third interior surfaces 601, 605, and 607. For example, first and second exterior surfaces 609 and 611 may be respectively offset from first and second interior surfaces 601 and 605 of region 501 by distances 615 and 617, which may extend in the first direction. Third exterior surface 613 may be offset from third interior surface 607 of region 501 by distance 619, which may extend in the second direction. In some implementations, region 501 may include stepped portion 621 defining fourth interior surface 623 of region 501, which may be offset from second exterior surface 611 of first temperature-controlled enclosure 125 by distance 625 in the first direction. Such a configuration may enable air gaps to be formed between the various exterior surfaces of first temperature-controlled enclosure 125 and the corresponding interior surfaces of region 501 that may provide some thermal insulative effects between first temperature-controlled enclosure 125 and second part 107 of process chamber 101. This may at least reduce the amount of conductive heat transfer from first temperature-controlled enclosure 125 to second part 107 of process chamber 101, and as such, may at least reduce the possibility of thermal energy from first temperature-controlled enclosure 125 affecting process conditions within process chamber 101.

According to some embodiments, second part 107 of process chamber 101 may also include an opening 911 extending in the first direction and fluidically connected to region 501. As will become more apparent below, opening 911 may expose a portion of first fluidic interface assembly 123 to enable first fluidic interface assembly 123 to be structurally connected to second part 107 via, for instance, fastener 507. Fastener 507 may engage with (e.g., threadedly engage with) opening 1003 in fourth interior surface 623 of region 501.

Fourth interior surface 623 may also include opening 1005, which may allow third fluidic interface assembly (or third fluidic disconnect) 133 to be structurally connected to second part 107 of process chamber 101 via a corresponding fastener. In some cases, second part 107 may be formed having internal cavity region 913 that, together with internal cavity region 109, may define a space (or enclosure) including process volume 313 in the first configuration between first and second parts 105 and 107.

First part 105 of process chamber 101 may include first and second regions 503 and 505 through which second and fourth fluidic interface assemblies 127 and 135 may be respectively routed. In some embodiments, first and second regions 503 and 505 may be respective recesses formed in first surface 1101 of first part 105. First surface 1101 of first part 105 may extend between second surface 1103 and third surface 1105 that may oppose one another in the axial direction. In some cases, second surface 1103 of first part 105 may form a contact interface with second surface 903 of second part 107 in the first configuration of process chamber 101. At least one fluidic seal may be provided between second surfaces 1103 and 903 of first and second parts 105 and 107 via at least one gasket arranged therebetween. For instance, second surface 1103 of first part 105 may include first and second grooves 1107 and 1109 configured to support first and second gaskets therein. In some cases, first and second grooves 1107 and 1109 may be formed circumferentially about internal cavity regions 109 and 913 of process chamber 101. It is also noted that first groove 1107 may be encircled by second groove 1109, and internal cavity region 109 may include first (e.g., lower) cavity region 1111 and second (e.g., upper) cavity region 1113. As such, when process chamber 101 is arranged in the first configuration, the first and second gaskets may be at least partially compressed at least partially within first and second grooves 1107 and 1109 and between first and second parts 105 and 107 to form, for instance, fluidic seals about internal cavity regions 109 and 913.

As seen in FIGS. 11 and 12, first and second regions 503 and 505 may extend in the axial direction. Proximal ends of first and second regions 503 and 505 may be fluidically connected to third region 1201, which may be recessed further into first part 105 of process chamber 101 than first and second regions 503 and 505. As such, recessed surface 1115 of third region 1201 may be disposed further from first surface 1101 of first part 105 than recessed surfaces 1117 and 1119 of first and second regions 503 and 505. In this manner, resting surface 1121 may be formed at a transition between third region 1201 and first and second regions 503 and 505. Distal ends of first and second regions 503 and 505 may be fluidically connected to fourth region 1203, which may be recessed further into first part 105 than third region 1201, but embodiments are not limited thereto. In some configurations, septal wall 1123 may be formed between first and second regions 503 and 505, and as such, each of first and second regions 503 and 505 may be bounded by at least three interior surfaces. For instance, first region 503 may be bounded by first and second interior surfaces 1125 and 1127, as well as recessed surface 1117. In this manner, each of first and second regions 503 and 505 may have first dimension 1205 extending in the axial direction, second dimension 1129 extending in the first direction, and third dimension 1207 extending in the second direction.

As will become more apparent below, when second fluidic interface assembly 127 is assembled as part of first part 105 of process chamber 101, various exterior surfaces of second temperature-controlled enclosure 129 may be offset from corresponding interior surfaces of first region 503, such as first and second interior surfaces 1125 and 1127 and recessed surface 1117. For example, first and second exterior surfaces 701 and 703 of second temperature-controlled enclosure 129 may be respectively offset from first and second interior surfaces 1125 and 1127 of first region 503 by distances 705 and 707, which may extend in the second direction. Third exterior surface 709 may be offset from recessed surface 1117 of first region 503 by distance 711, which may extend in the first direction. In some implementations, first through fourth regions 503, 505, 1201, and 1203 may be covered (or otherwise concealed) by cover plate 509, which may be coupled (e.g., detachably coupled) to first part 105 via a plurality of fasteners, such as fasteners 511. Cover plate 509 may include a plurality of through-holes 513 through which fasteners 511 may extend and engage (e.g., threadedly engage) with respective openings 1209 in first part 105 of process chamber 101. As such, fourth exterior surface 713 of second temperature-controlled enclosure 129 may be offset from interior surface 715 of cover plate 509 by distance 717, which may extend in the first direction. Such a configuration may enable air gaps to be formed between the various exterior surfaces of second temperature-controlled enclosure 129 and the corresponding interior surfaces of first region 503 and cover plate 509 that may provide some thermal insulative effects between second temperature-controlled enclosure 129 and first part 105 of process chamber 101. This may at least reduce the amount of conductive heat transfer from second temperature-controlled enclosure 129 to first part 105 of process chamber 101, and as such, may at least reduce the possibility of thermal energy from second temperature-controlled enclosure 129 affecting process conditions within process chamber 101.

According to some embodiments, and as will become more apparent below, recessed surface 1115 of third region 1201 of first part 105 of process chamber 101 may include opening 1131, which enables second fluidic interface assembly 127 to be structurally connected to first part 105 via, for instance, fastener 515. In some cases, fastener 515 may engage with (e.g., threadedly engage with) opening 1131 in recessed surface 1115. In addition, recessed surface 1115 may also include opening 1133 to allow fourth fluidic interface assembly 135 to be structurally connected to first part 105 of process chamber 101 via a corresponding fastener.

### Thermally Controlled Disconnects

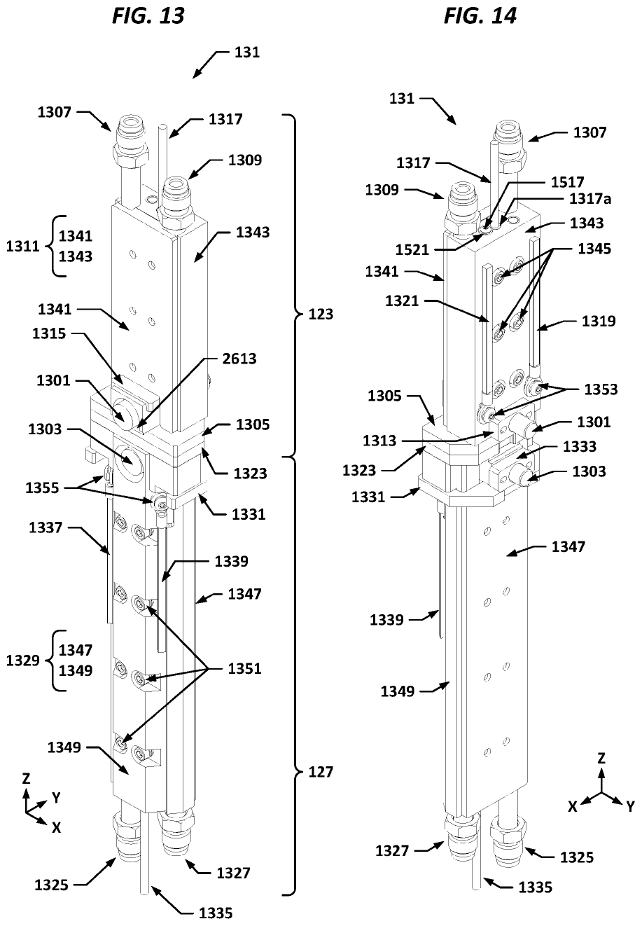

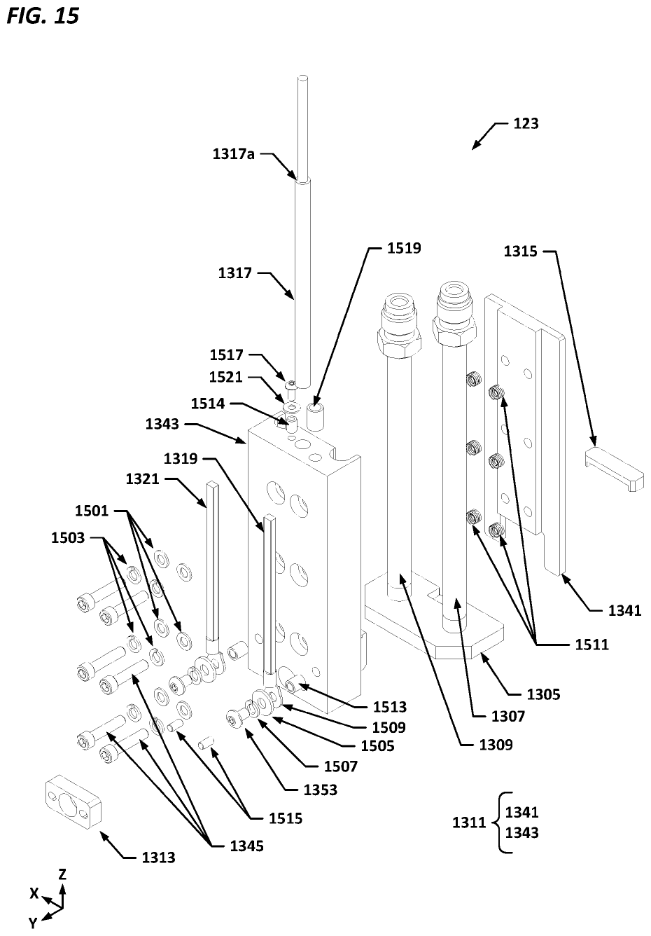

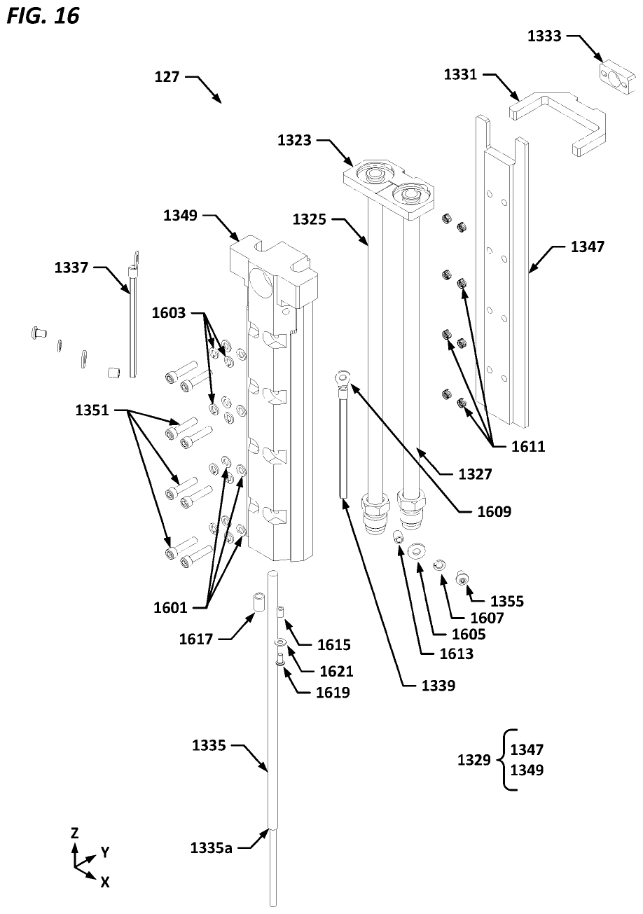

FIGS. 13 and 14 schematically illustrate perspective views of the thermally controlled disconnect of FIG. 5 according to some embodiments. FIG. 15 schematically illustrates an exploded perspective view of a first fluidic interface assembly of the thermally controlled disconnect of FIG. 5 according to some embodiments. FIG. 16 schematically illustrates an exploded perspective view of a second fluidic interface assembly of the thermally controlled disconnect of FIG. 5 according to some embodiments.

Referring to FIGS. 13-16, thermally controlled disconnect 131 may include first and second fluidic interface assemblies 123 and 127, which may be coupled to first and second parts 105 and 107 of process chamber 101 via first and second fasteners 1301 and 1303. First and second fasteners 1301 and 1303 may correspond to fasteners 507 and 515 depicted in FIG. 5. First fluidic interface assembly 123 may include first fluidic disconnect 1305, first and third conduits 1307 and 1309, first temperature-controlled enclosure 1311, first and second thermal insulators 1313 and 1315, first heating element 1317, and first and second thermocouples 1319 and 1321. Second fluidic interface assembly 127 may include second fluidic disconnect 1323, second and fourth conduits 1325 and 1327, second temperature-controlled enclosure 1329, third and fourth thermal insulators 1331 and 1333, second heating element 1335, and third and fourth thermocouples 1337 and 1339.

First temperature-controlled enclosure 1311 may include first and second enclosure portions 1341 and 1343, which may be coupled to one another via one or more fasteners, such as fasteners 1345. Second temperature-controlled enclosure 1329 may include third and fourth enclosure portions 1347 and 1349, which may be coupled to one another via one or more fasteners, such as fasteners 1351. First and second thermocouples 1319 and 1321 may be connected to second enclosure portion 1343 via one or more fasteners, such as fasteners 1353. Third and fourth thermocouples 1337 and 1339 may be connected to fourth enclosure portion 1349 via one or more fasteners, such as fasteners 1355. In some embodiments, respective groups of washers 1501 and lock washers 1503 may be positioned between heads of corresponding fasteners 1345 and second enclosure portion 1343, and respective groups of washers 1601 and 1603 may be disposed between heads of respective fasteners 1351 and fourth enclosure portion 1349. Respective groups of washers 1505 and lock washers 1507 may be positioned between heads of corresponding fasteners 1353 and respective connector portions 1509 of first and second thermocouples 1319 and 1321. In a similar fashion, respective groups of washers 1605 and lock washers 1607 may be positioned between heads of corresponding fasteners 1355 and respective connector portions 1609 of third and fourth thermocouples 1337 and 1339. As will become more apparent below, threaded inserts (or bushings) 1511, 1513, and 1514 may be respectively utilized in association with fasteners 1345, 1353, and 1517 to provide more durable connections. Likewise, threaded inserts (or bushings) 1611, 1613, and 1614 may be respectively utilized in association with fasteners 1351, 1355, and 1615 to provide more durable connections. Other threaded inserts (or bushings) 1519 and 1617 may be respectively utilized in association with second and fourth enclosure portions 1343 and 1349 to provide connection points for one or more optional grounding wires.

According to some embodiments, first, second, third, and fourth enclosure portions 1341, 1343, 1347, and 1349 may be formed of any suitable material, such as any suitable thermally conductive material. For example, at least one of first, second, third, and fourth enclosure portions 1341, 1343, 1347, and 1349 may be formed of or include one or more of aluminum, aluminum nitride, beryllium oxide, brass, bronze, carbon, copper, gold, iron, silicon, silicon carbide, silver, steel, tungsten, zinc, and/or the like. In some cases, at least one of first, second, third, and fourth enclosure portions 1341, 1343, 1347, and 1349 may be formed of at least one base material and at least one coating having a higher thermal conductivity than the at least one base material. For instance, a base material of at least one of first, second, third, and fourth enclosure portions 1341, 1343, 1347, and 1349 may be aluminum and may be coated with, for instance, aluminum nitride, but embodiments are not limited thereto. In some cases, the additional coating may be formed in association with those surfaces interfacing with one of first, second, third, and fourth conduits 1307, 1325, 1309, and 1327, and not formed on surfaces exposed to surfaces of process chamber 101. It is also noted that first, second, third, and fourth enclosure portions 1341, 1343, 1347, and 1349 may be formed in any suitable manner, such as additively manufactured, casted, machined, stamped, and/or the like.

First, second, third, and fourth thermal insulators 1313, 1315, 1331, and 1333 may be formed of any suitable material, such as any suitable thermally insulative material. For example, at least one of first, second, third, and fourth thermal insulators 1313, 1315, 1331, and 1333 may be formed of or include one or more of carbon fiber, ceramics, insulon™, fiberglass, nylon, perlite, porcelain, quartz, one or more resins, rubber, silica, and/or the like. In some cases, at least one of first, second, third, and fourth thermal insulators 1313, 1315, 1331, and 1333 may be formed of at least one base material and at least one coating having a lower thermal conductivity than the at least one base material. Whatever the case, first, second, third, and fourth thermal insulators 1313, 1315, 1331, and 1333 may be formed in any suitable manner, such as additively manufactured, casted, impregnated, molded, machined, stamped, weaved, and/or the like.

First, second, third, and fourth conduits 1307, 1309, 1325, and 1335, as well as first and second fluidic disconnects 1305 and 1323 and other conduits, connectors, etc., of system 400, may be formed of any suitable corrosion resistant material, such as aluminum, brass, bronze, carbon steel, copper, stainless steel, titanium, and/or the like.

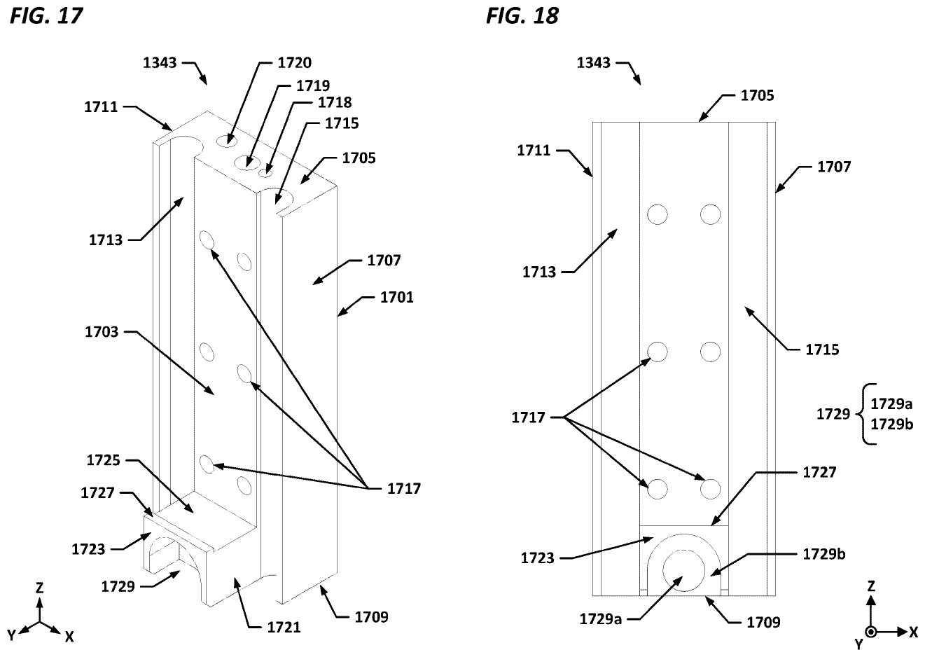

FIGS. 17-21 schematically illustrate various views of a second enclosure portion of the first fluidic interface assembly of FIG. 15 according to some embodiments.

Referring to FIGS. 17-21, second enclosure portion 1343 may have a main body formed as a generally rectangular prism including first surface 1701 (e.g., a surface facing away from second part 107 of process chamber 101 when assembled therewith) opposing second surface 1703 (e.g., a surface facing second part 107 when assembled therewith) in the first direction. Although the main body of second enclosure portion 1343 will be described having a generally rectangular prism configuration, embodiments are not limited thereto. For instance, second enclosure portion 1343 may have any suitable geometric configuration, such as a generally cylindrical, generally prismatic, generally conical, generally polyhedral, etc., configuration.

First and second surfaces 1701 and 1703 of second enclosure portion 1343 may be bounded by one or more peripheral surfaces, such as peripheral surfaces (or surfaces) 1705, 1707, 1709, and 1711 that may be connected to one another. Second surface 1703 may include one or more recessed portions (or channels), such as first and second recessed portions 1713 and 1715 configured to receive or otherwise interface with first and third conduits 1307 and 1309 in an assembled state of first temperature-controlled enclosure 1311. In some cases, one or more surfaces defining first and second recessed portions 1713 and 1715 may abut against corresponding portions of first and third conduits 1307 and 1309 to promote conductive heat transfer between second enclosure portion 1343 and first and third conduits 1307 and 1309. To this end, respective contours of first and second recessed portions 1713 and 1715 may correspond with respective contours of first and third conduits 1307 and 1309 to also promote conductive heat transfer between second enclosure portion 1343 and first and third conduits 1307 and 1309. It is also noted that, in an assembled state of first temperature-controlled enclosure 1311, first and third conduits 1307 and 1309 may be partially (or fully) received in first and second recessed portions 1713 and 1715.

According to various embodiments, second surface 1703 of second enclosure portion 1343 may also include a plurality of first through-holes 1717, which may be configured to not only allow fasteners 1345 to pass therethrough, but also enable first and second enclosure portions 1341 and 1343 to be assembled together with first and third conduits 1307 and 1309 extending therebetween. Although second enclosure portion 1343 is shown including six first through-holes 1717, embodiments are not limited thereto. For example, second enclosure portion 1343 may include less than six first through-holes, such as one, two, three, four, etc., first through-holes, or may include more than six first through-holes, such as seven, eight, nine, ten, etc., first through-holes.

In some implementations, the main body of second enclosure portion 1343 may include openings 1718, 1719, and 1720 in surface 1705 that extend in the axial direction.

Opening 1719 may be configured to receive at least a portion of first heating element 1317 therein. The size of opening 1719 in a plane perpendicular (or substantially perpendicular) to the axial direction may allow for a clearance (or transition) fit with first heating element 1317 in a non-operational state of first heating element 1317. This may allow for differential expansion between first heating element 1317 and second enclosure portion 1343 in an operational state of first heating element 1317. As such, opening 1718 may be utilized in association with fastener 1517 and washer 1521 to constrain the axial displacement of first heating element 1317 within opening 1719, such as shown in FIG. 14. For example, first heating element 1317 may be slidably received in opening 1719 and washer 1521 may be coupled to second enclosure portion 1343 via threaded engagement between fastener 1517 and threaded insert 1514. In this manner, respective portions of washer 1521 may be disposed between a head portion of fastener 1517 and at least one of opening 1719 (and, thereby, upper surface 1317a of first heating element 1317) and surface 1705 of the main body of second enclosure portion 1343. As such, the portion of washer 1521 overlapping with opening 1719 and a portion of upper surface 1317a of first heating element 1317 may constrain axial displacement of first heating element 1317 to prevent first heating element 1317 from sliding out of opening 1719. In some cases, first heating element 1317 may be compressible so as to allow opening 1719 to be sized for a tight or interference fit with first heating element 1317 in a non-operational state of first heating element 1317. This may additionally or alternatively be utilized to constrain axial displacement of first heating element 1317 to prevent first heating element 1317 from sliding out of opening 1719. In some cases, opening 1720 may include threaded insert 1519 to provide a connection point to ground first fluidic interface assembly 123 via, for example, a grounding wire.

The main body of second enclosure portion 1343 may also include protrusion 1721 extending from second surface 1703 in the first direction by a determined amount. As such, protrusion 1721 may include distal surface 1723 and resting surface 1725 extending between second surface 1703 and distal surface 1723. As will become more apparent below, resting surface 1725 may abut against a corresponding surface of second thermal insulator 1315 in an assembled state of first fluidic interface assembly 123. A distal end of resting surface 1725 may include retaining protrusion 1727 extending in the axial direction and configured to restrain movement of second thermal insulator 1315 in the first direction in an assembled state of first fluidic interface assembly 123. It is also noted that second enclosure portion 1343 may include through-hole 1729 extending from distal surface 1723 through first surface 1701 in the first direction. In some cases, through-hole 1729 may be counterbored, and thereby, may include first portion 1729a and second portion 1729b aligned with first portion 1729a. It is noted, however, that when first and second portions 1729a and 1729b are viewed in a direction opposite the first direction, a shape of second portion 1729b may be different than a shape of first portion 1729a. For example, first portion 1729a may have a circular shape, whereas second portion 1729b may have a D-shape configuration. As seen in FIG. 18, a size of second portion 1729b may be greater than a corresponding size of first portion 1729a, but embodiments are not limited thereto. It is also noted that the flat region of second portion 1729b of through-hole 1729 may also extend through a portion of surface 1709, as seen in FIG. 21. In this manner, through-hole 1729 may be configured to allow fastener 507 to pass therethrough and engage with opening 1003 in fourth interior surface 623 of region 501 of second part 107 of process chamber 101. In some implementations, a part of the head portion of fastener 507 may extend from the opening in surface 1709 that corresponds to second portion 1729b.

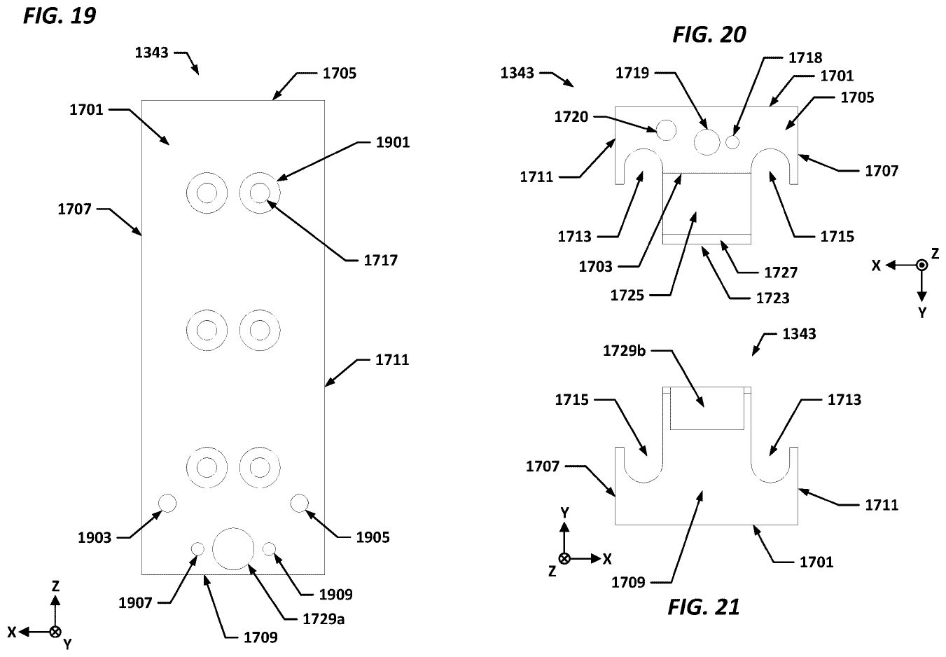

Referring to FIG. 19, first through-holes 1717 may include counterbored portions 1901 in first surface 1701. Respective diameters of counterbored portions 1901 may be greater than corresponding diameters of first through-holes 1717. It is also noted that the main body of second enclosure portion 1343 may include openings 1903, 1905, 1907, and 1909 formed in first surface 1701 and extending towards second surface 1703 in the first direction. Openings 1903 and 1905 may provide connection points for fasteners 1353 to allow first and second thermocouples 1319 and 1321 to be connected to second enclosure portion 1343. In some cases, openings 1903 and 1905 may include threaded inserts 1513 that are configured to engage with fasteners 1353. First and second thermocouples 1319 and 1321 may be positioned adjacent to first surface 1701 and in correspondence with first and second recessed portions 1713 and 1715 to allow variable temperature feedback information to be provided to, for instance, thermal system 325. Such a configuration may also allow the temperature of first and third conduits 1307 and 1309 to be distinctly monitored relative to the temperature of second enclosure portion 1343 in association with first and second recessed portions 1713 and 1715.

Openings 1907 and 1909 may be configured to provide alignment features with corresponding alignment features in first thermal insulator 1313, as will become more apparent below. In some cases, openings 1907 and 1909 may be configured to receive first portions of alignment pins 1515 therein. Second portions of alignment pins 1515 may be at least partially received in alignment openings 2501 in first thermal insulator 1313 when first thermal insulator 1313 is assembled as part of first fluidic interface assembly 123.

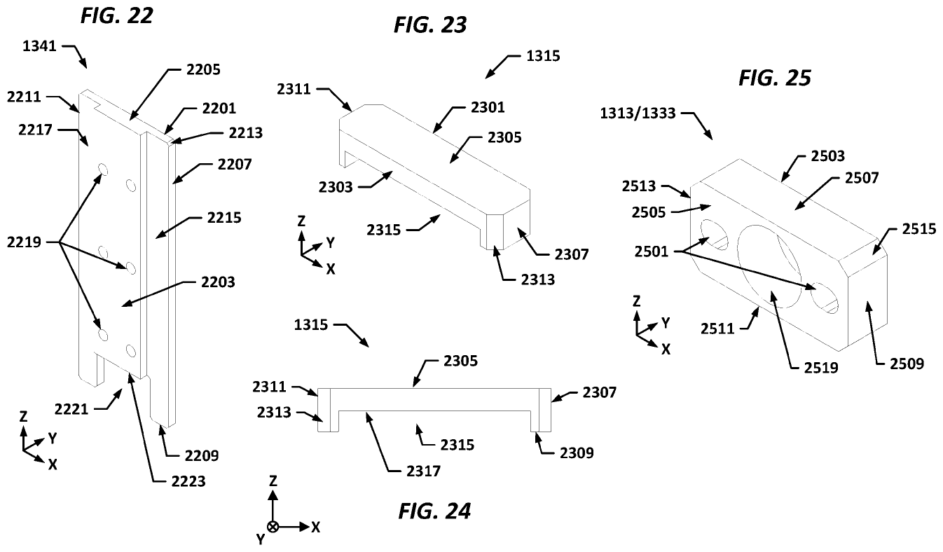

FIG. 22 schematically illustrates a perspective view of a first enclosure portion of the first fluidic interface assembly of FIG. 15 according to some embodiments.

Referring to FIG. 22, first enclosure portion 1341 may be a generally rectangular plate-shaped body having first surface 2201 (e.g., a surface facing away from second part 107 of process chamber 101 when assembled therewith) opposing second surface 2203 (e.g., a surface facing second part 107 when assembled therewith) in the first direction. Although first enclosure portion 1341 will be described as having a generally rectangular plate-shaped configuration, embodiments are not limited thereto. For instance, first enclosure portion 1341 may have any suitable geometric configuration, such as a generally circular, generally elliptical, generally triangular, generally pentagonal, generally hexagonal, etc., configuration.

First and second surfaces 2201 and 2203 of first enclosure portion 1341 may be bounded by one or more peripheral surfaces, such as peripheral surfaces (or surfaces) 2205, 2207, 2209, and 2211 that may be connected to one another via one or more other peripheral surfaces, such as peripheral surface (or surface) 2213. Second surface 2203 may include one or more recessed portions (or channels), such as first and second recessed portions 2215 and 2217. In various embodiments, first and second recessed portions 2215 and 2217 may be configured to receive or otherwise interface with first and third conduits 1307 and 1309 in an assembled state of first fluidic interface assembly 123. In some instances, first and second recessed portions 2215 and 2217 may abut against corresponding portions of first and third conduits 1307 and 1309. As shown, first and second recessed portions 2215 and 2217 may have flat (or substantially flat) surfaces versus the contoured surfaces defining first and second recessed portions 1713 and 1715 in second enclosure portion 1343, but embodiments are not limited thereto. For instance, first and second recessed portions 2215 and 2217 of first enclosure portion 1341 may have contour surfaces similar to the contour surfaces defining first and second recessed portions 1713 and 1715 in second enclosure portion 1343. The sizing of first and third conduits 1307 and 1309 relative to the sizing of first and second recessed portions 1713, 1715, 2215, and 2217 in first and second enclosure portions 1341 and 1343 may cause, at least in part, first and second enclosure portions 1341 and 1343 to be spaced apart from one another by distance 627 in the first direction in an assembled state of first fluidic interface assembly 123. In other cases, second surfaces 1703 and 2203 of first and second enclosure portions 1341 and 1343 may abut against one another in an assembled state of first fluidic interface assembly 123.

Second surface 2203 may also include a plurality of first openings 2219, which may be configured to engage with fasteners 1345 to enable first and second enclosure portions 1341 and 1343 to be assembled together with first and third conduits 1307 and 1309 extending therebetween. In some cases, first openings 2219 may respectively include a corresponding threaded insert of threaded inserts 1511, which may correspondingly engage with respective fasteners of fasteners 1345. Although first enclosure portion 1341 is shown including six first openings 2219, embodiments are not limited thereto. For example, first enclosure portion 1341 may include less than six first openings, such as one, two, three, four, etc., first openings, or may include more than six first openings, such as seven, eight, nine, ten, etc., first openings.

According to some implementations, first enclosure portion 1341 may also include through-hole (or slotted region) 2221 extending from first surface 2201 to second surface 2203. Through-hole 2221 may be sized to allow protrusion 1721 of second enclosure portion 1343 to extend therethrough in an assembled state of first fluidic interface assembly 123 such as shown in FIGS. 8 and 13. In some cases, surface 2223 (which partially bounds through-hole 2221) may abut against resting surface 1725 of protrusion 1721 in an assembled state of first fluidic interface assembly 123.

FIGS. 23 and 24 schematically illustrate various views of a second thermal insulator of the first fluidic interface assembly of FIG. 15 according to some embodiments.

Referring to FIGS. 23 and 24, second thermal insulator 1315 may be formed as a generally rectangular prism including first surface 2301 opposing second surface 2303 in the first direction. Although second thermal insulator 1315 will be described having a generally rectangular prism configuration, embodiments are not limited thereto. For instance, second thermal insulator 1315 may have any suitable geometric configuration, such as a generally cylindrical, generally prismatic, generally conical, generally polyhedral, etc., configuration.

First and second surfaces 2301 and 2303 of second thermal insulator 1315 may be bounded by one or more peripheral surfaces, such as peripheral surfaces (or surfaces) 2305, 2307, 2309, and 2311 that may be connected to one another. In some cases, one or more chamfered surfaces (such as chamfered surface 2313) may connect adjacent peripheral surfaces to one another. In addition, second thermal insulator 1315 may include opening 2315 in surface 2309 that extends in the axial direction towards surface 2305. Opening 2315 may also extend from second surface 2303 through first surface 2301 in the first direction. In some embodiments, opening 2315 may be sized to allow terminating surface 2317 of opening 2315 to rest upon resting surface 1725 of protrusion 1721 of second enclosure portion 1343 when second thermal insulator 1315 is included as part of first fluidic interface assembly 123. It is also noted that, in an assembled state of first fluidic interface assembly 123, surface 2305 of second thermal insulator 1315 may abut against terminating surface 911s of opening 911 in second part 107 of process chamber 101. This may prevent some contact between second part 107 and first enclosure portion 1341, and as such, may at least partially insulate second part 107 of process chamber 101 from first enclosure portion 1341.

FIG. 25 schematically illustrates a perspective view of a first thermal insulator of the first fluidic interface assembly of FIG. 15 according to some embodiments.

Referring to FIG. 25, first thermal insulator 1313 may be formed as a generally rectangular prism including first surface 2503 opposing second surface 2505 in the first direction. Although first thermal insulator 1313 will be described having a generally rectangular prism configuration, embodiments are not limited thereto. For instance, first thermal insulator 1313 may have any suitable geometric configuration, such as a generally cylindrical, generally prismatic, generally conical, generally polyhedral, etc., configuration.

First and second surfaces 2503 and 2505 of first thermal insulator 1313 may be bounded by one or more peripheral surfaces, such as peripheral surfaces (or surfaces) 2507, 2509, 2511, and 2513 that may be connected to one another. In some cases, one or more chamfered surfaces (such as chamfered surface 2515) may connect adjacent peripheral surfaces to one another. As previously mentioned, first thermal insulator 1313 may also include alignment openings 2501 extending from second surface 2505 through first surface 2503 in the first direction. Alignment openings 2501 may, in some embodiments, have a slotted or stadium-shaped configuration and may be configured to interface with alignment pins 1515 in an assembled state of first fluidic interface assembly 123. First thermal insulator 1313 may also include through-hole 2519 extending from second surface 2505 through first surface 2503 in the first direction. Through-hole 2519 may be sized to allow first fastener 1301 to extend therethrough.

According to some embodiments, first thermal insulator 1313 may be positioned between second enclosure portion 1343 and fourth interior surface 623 of second part 107 of process chamber 101 in an assembled state of first fluidic interface assembly 123. This may prevent some contact between second part 107 and second enclosure portion 1343, and as such, may at least partially insulate second part 107 of process chamber 101 from second enclosure portion 1343. In some embodiments, first and second surfaces 2503 and 2505 may respectively abut against first surface of second enclosure portion 1343 and fourth interior surface 623 of region 501 of second part 107 of process chamber 101 in an assembled state of first fluidic interface assembly 123 and process chamber 101.

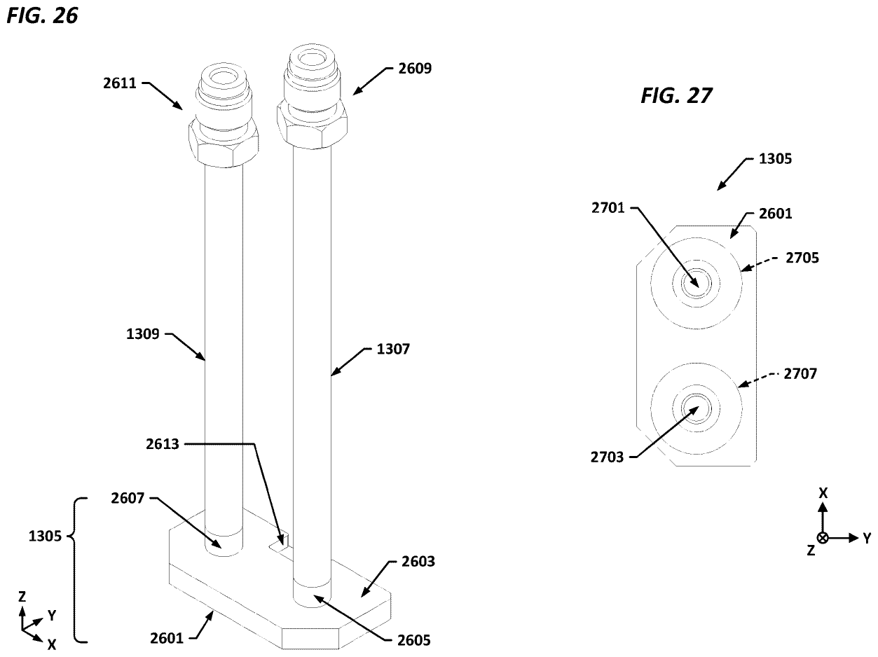

FIGS. 26 and 27 schematically illustrate perspective and orthographic views of a first fluid disconnect of the first fluidic interface assembly of FIG. 15 according to some embodiments.

Referring to FIGS. 26 and 27, first fluidic disconnect 1305 may be formed as a plate-shaped body having first surface 2601 opposing second surface 2603 in the axial direction. First and second through-holes 2701 and 2703 may extend from first surface 2601 through second surface 2603 in the axial direction. Accordingly, when process chamber 101 is arranged in the first configuration (such as the configuration shown in FIG. 1), first surface 2601 of first fluidic disconnect 1305 may mate with first surface 3601 of second fluidic disconnect 1323 in a manner that first and second conduits 1307 and 1325 become fluidically connected with one another and third and fourth conduits 1309 and 1327 become fluidically connected with one another. As will become more apparent below, gaskets 2705 and 2707 (shown in phantom in FIG. 27) may be at least partially compressed between first and second fluidic disconnects 1305 and 1323 to enhance a sealing effect therebetween. Gaskets 2705 and 2707 may respective encircle first and second through-holes 2701 and 2703 to at least fluidically isolate first and third conduits 1307 and 1309 from one another within first fluidic disconnect 1305.

In some implementations, proximal ends of first and third conduits 1307 and 1309 may be fluidically and structurally connected to first and second through-holes 2701 and 2703 via connection points (or connectors) 2605 and 2607. Distal ends of first and third conduits 1307 and 1309 may respectively include corresponding fluidic disconnects (such as quick disconnects) 2609 and 2611 to allow first fluidic disconnect 1305 to be installed and/or replaced in system 103 relatively easily.

According to various embodiments, surfaces 2209 and 1709 of first and second enclosure portions 1341 and 1343 may abut against second surface 2603 in an assembled state of first fluidic interface assembly 123. In addition, second surface 2603 of first fluidic disconnect 1305 may include recessed (or notched) portion 2613, which may be configured to receive at least a part of the head portion of first fastener 1301 therein in an assembled state of first fluidic interface assembly 123 with second part 107 of process chamber 101.

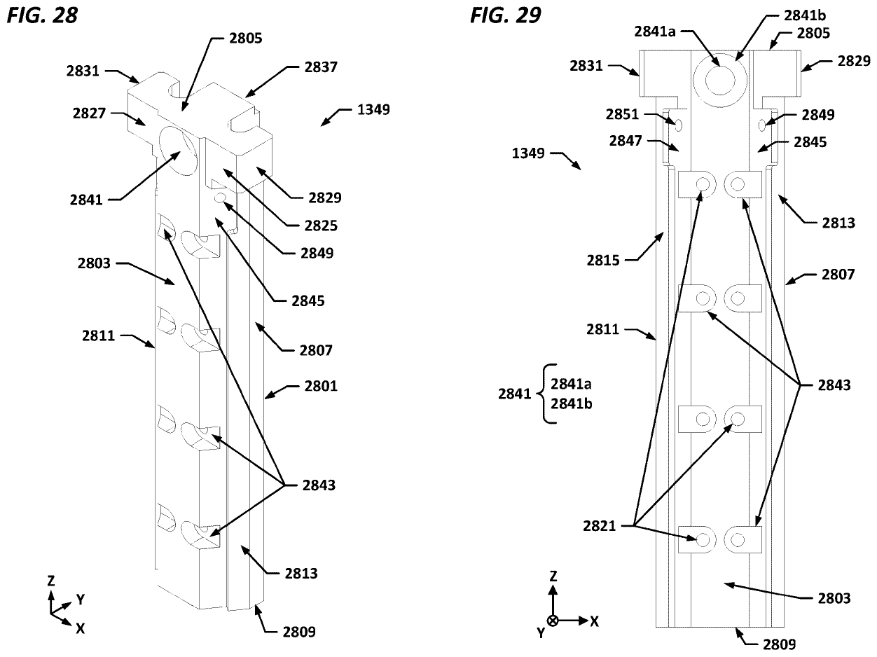

FIGS. 28-32 schematically illustrate various views of a fourth enclosure portion of the second fluidic interface assembly of FIG. 16 according to some embodiments.

Referring to FIGS. 28-32, fourth enclosure portion 1349 may have a main body formed as a generally rectangular prism including first surface 2801 (e.g., a surface facing away from first part 105 of process chamber 101 when assembled therewith) opposing second surface 2803 (e.g., a surface facing second part 107 when assembled therewith) in the first direction. Although the main body of fourth enclosure portion 1349 will be described having a generally rectangular prism configuration, embodiments are not limited thereto. For instance, fourth enclosure portion 1349 may have any suitable geometric configuration, such as a generally cylindrical, generally prismatic, generally conical, generally polyhedral, etc., configuration.

First and second surfaces 2801 and 2803 of fourth enclosure portion 1349 may be bounded by one or more peripheral surfaces, such as peripheral surfaces (or surfaces) 2805, 2807, 2809, and 2811 that may be connected to one another. In some cases, surface 2807 may be connected to second surface 2803 via chamfered surface 2813, and surface 2811 may be connected to second surface 2803 via chambered surface 2815. First surface 2801 of fourth enclosure portion 1349 may include one or more recessed portions (or channels), such as first and second recessed portions 2817 and 2819 configured to receive or otherwise interface with second and fourth conduits 1325 and 1327 in an assembled state of second temperature-controlled enclosure 1329. In some cases, one or more surfaces defining first and second recessed portions 2817 and 2819 may abut against corresponding portions of second and fourth conduits 1325 and 1327 to promote conductive heat transfer between fourth enclosure portion 1349 and second and fourth conduits 1325 and 1327. To this end, respective contours of first and second recessed portions 2817 and 2819 may correspond with respective contours of second and fourth conduits 1325 and 1327 to also promote conductive heat transfer between fourth enclosure portion 1349 and second and fourth conduits 1325 and 1327. It is also noted that, in an assembled state of second temperature-controlled enclosure 1329, second and fourth conduits 1325 and 1327 may be partially (or fully) received in first and second recessed portions 2817 and 2819.

According to various embodiments, first surface 2801 of fourth enclosure portion 1349 may also include a plurality of first through-holes 2821, which may be configured to not only allow fasteners 1351 to pass therethrough, but also enable third and fourth enclosure portions 1347 and 1349 to be assembled together with second and fourth conduits 1325 and 1327 extending therebetween. Although fourth enclosure portion 1349 is shown including eight first through-holes 2821, embodiments are not limited thereto. For example, fourth enclosure portion 1349 may include less than eight first through-holes, such as one, two, three, four, etc., first through-holes, or may include more than eight first through-holes, such as nine, ten, eleven, twelve, etc., first through-holes.

In some implementations, the main body of fourth enclosure portion 1349 may include openings 2823, 3201, and 3203 in surface 2809 that extend in the axial direction. Opening 2823 may be configured to receive at least a portion of second heating element 1335 therein. The size of opening 2823 in a plane perpendicular (or substantially perpendicular) to the axial direction may allow for a clearance (or transition) fit with second heating element 1335 in a non-operational state of second heating element 1335. This may allow for differential expansion between second heating element 1335 and fourth enclosure portion 1349 in an operational state of second heating element 1335. As such, opening 3201 may be utilized in association with fastener 1619 and washer 1621 to constrain the axial displacement of second heating element 1335 within opening 2823. For example, second heating element 2823 may be slidably received in opening 2823 and washer 1621 may be coupled to fourth enclosure portion 1349 via threaded engagement between fastener 1619 and threaded insert 1615. In this manner, respective portions of washer 1621 may be disposed between a head portion of fastener 1619 and at least one of opening 2823 (and, thereby, lower surface 1335a of second heating element 1335) and surface 2809 of the main body of fourth enclosure portion 1349. As such, the portion of washer 1621 overlapping with opening 2823 and a portion of lower surface 1335a of second heating element 1335 may constrain axial displacement of second heating element 1335 to prevent second heating element 1335 from sliding out of opening 2823. In some cases, second heating element 1335 may be compressible so as to allow opening 2823 to be sized for a tight or interference fit with second heating element 1335 in a non-operational state of second heating element 1335. This may additionally or alternatively be utilized to constrain axial displacement of second heating element 1335 to prevent second heating element 1335 from sliding out of opening 2823. In some implementations, opening 3203 may include threaded insert 1617 to provide a connection point to ground second fluidic interface assembly 127 via, for example, a grounding wire.

The main body of fourth enclosure portion 1349 may also include protrusions 2825 and 2827 respectively extending from surfaces 2807 and 2811 in the second direction (or a direction opposite the second direction) by a determined amount. As such, protrusions 2825 and 2827 may respectively include distal surfaces 2829 and 2831 and resting surfaces 2833 and 2835. In this manner, fourth enclosure portion 1349 may have T-shape configuration with the main body forming a web portion extending in the axial direction and protrusions 2825 and 2827 forming flange portions extending in the second direction (or a direction opposite the second direction. As will become more apparent below, resting surfaces 2833 and 2835 of protrusions 2825 and 2827 may be spaced apart from corresponding portions of resting surface 1121 of first part 105 of process chamber 101 by third thermal insulator 1331 in an assembled state of process chamber 101 including second fluidic interface assembly 127.

Fourth enclosure portion 1349 may also include protrusion 2837 extending from first surface 2801 in the first direction by a determined amount. As such, protrusion 2837 may include distal surface 2839. As will become more apparent below, in an assembled state of first part 105 of process chamber 101 including second fluidic interface assembly 127, distal surface 2839 of protrusion 2837 may be spaced apart from recessed surface 1115 of third region 1201 of first part 105 by distance 801 extending in the first direction. In some cases, fourth thermal insulator 1333 (which may be configured similar to first thermal insulator 1313) may be disposed between distal surface 2839 and recessed surface 1115, and in some cases, first and second surfaces 2503 and 2505 of fourth thermal insulator 1333 may respectively abut against distal surface 2839 and recessed surface 1115 of third region 1201 of first part 105 of process chamber 101. It is also noted that fourth enclosure portion 1349 may include through-hole 2841 extending from distal surface 2839 through second surface 2803 in a direction opposite the first direction. In some cases, through-hole 2841 may be counterbored, and thereby, may include first portion 2841a and second portion 2841b aligned with first portion 2841a. As seen in FIG. 29, a size (e.g., diameter) of second portion 2841b may be greater than a corresponding size (e.g., diameter) of first portion 2841a, but embodiments are not limited thereto. To this end, through-hole 2841 may be configured to allow second fastener 1303 to pass therethrough and engage with opening 1131 in third region 1201 of first part 105 of process chamber 101.

In some implementations, first through-holes 2821 may include counterbored portions 2843 in second surface 2803. Further, respective shapes of counterbored portions 2843 may be different from corresponding shapes of first through-holes 2821 when viewed in the first direction. For instance, first through-holes 2821 may have respective circular shapes and counterbored portions 2843 may have corresponding D-shapes, but embodiments are not limited thereto. Sizes of counterbored portions 2843 may be greater than respective corresponding sizes of first through-holes 2821, but embodiments are not limited thereto.

According to some embodiments, chamfered surfaces 2813 and 2815 may respectively include recessed portions 2845 and 2847, which may be sized and shaped to allow fourth and third thermocouples 1337 and 1339 to be respectively connected to fourth enclosure portion 1349 via respective openings 2849 and 2851 in recessed portions 2845 and 2847 and fasteners 1355. In some cases, openings 2849 and 2851 may include threaded inserts 1613 that are configured to engage with fasteners 1355. Third and fourth thermocouples 1337 and 1339 may be positioned adjacent to second surface 2803 and in correspondence with first and second recessed portions 2817 and 2819 to allow variable temperature feedback information to be provided to, for instance, thermal system 325. Such a configuration may also allow the temperature of second and fourth conduits 1325 and 1327 to be distinctly monitored relative to the temperature of fourth enclosure portion 1349 in association with first and second recessed portions 2817 and 2819.

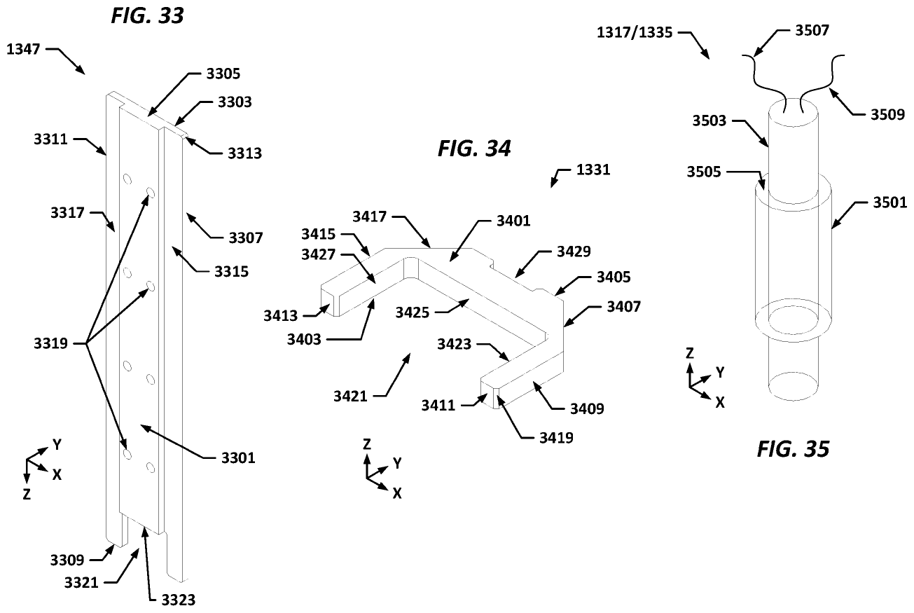

FIG. 33 schematically illustrates a perspective view of a third enclosure portion of the second fluidic interface assembly of FIG. 16 according to some embodiments.

Referring to FIG. 33, third enclosure portion 1347 may be a generally rectangular plate-shaped body having first surface 3301 (e.g., a surface facing away from first part 105 of process chamber 101 when assembled therewith) opposing second surface 3303 (e.g., a surface facing first part 105 when assembled therewith) in the first direction. Although third enclosure portion 1347 will be described as having a generally rectangular plate-shaped configuration, embodiments are not limited thereto. For instance, third enclosure portion 1347 may have any suitable geometric configuration, such as a generally circular, generally elliptical, generally triangular, generally pentagonal, generally hexagonal, etc., configuration.

First and second surfaces 3301 and 3303 of third enclosure portion 1347 may be bounded by one or more peripheral surfaces, such as peripheral surfaces (or surfaces) 3305, 3307, 3309, and 3311 that may be connected to one another via one or more other peripheral surfaces, such as peripheral surface (or surface) 3313. First surface 3301 may include one or more recessed portions (or channels), such as first and second recessed portions 3315 and 3317. In various embodiments, first and second recessed portions 3315 and 3317 may be configured to receive or otherwise interface with second and fourth conduits 1325 and 1327 in an assembled state of second fluidic interface assembly 127. In some instances, first and second recessed portions 3315 and 3317 may abut against corresponding portions of second and fourth conduits 1325 and 1327. As shown, first and second recessed portions 3315 and 3317 may have flat (or substantially flat) surfaces versus the contoured surfaces defining first and second recessed portions 2817 and 2819 in fourth enclosure portion 1349, but embodiments are not limited thereto. For instance, first and second recessed portions 3315 and 3317 of third enclosure portion 1347 may have contour surfaces similar to the contour surfaces defining first and second recessed portions 2817 and 2819 in fourth enclosure portion 1349. The sizing of second and fourth conduits 1325 and 1327 relative to the sizing of first and second recessed portions 2817, 2819, 3317, and 3319 in third and fourth enclosure portions 1347 and 1349 may cause, at least in part, third and fourth enclosure portions 1347 and 1349 to be spaced apart from one another by distance 719 in the first direction in an assembled state of second fluidic interface assembly 127. In other implementations, first surfaces 2801 and 3301 of third and fourth enclosure portions 1347 and 1349 may abut against one another in an assembled state of second fluidic interface assembly 127.

First surface 3301 of third enclosure portion 1347 may also include a plurality of first openings 3319, which may be configured to engage with fasteners 1351 to enable third and fourth enclosure portions 1347 and 1349 to be assembled together with second and fourth conduits 1325 and 1327 extending therebetween. In some cases, first openings 3319 may respectively include a corresponding threaded insert of threaded inserts 1611, which may correspondingly engage with respective fasteners of fasteners 1351. Although third enclosure portion 1347 is shown including eight first openings 3319, embodiments are not limited thereto. For example, third enclosure portion 3341 may include less than eight first openings, such as one, two, three, four, etc., first openings, or may include more than eight first openings, such as nine, ten, eleven, twelve, etc., first openings.

According to some implementations, third enclosure portion 1347 may also include through-hole (or slotted region) 3321 extending from first surface 3301 to second surface 3303. Through-hole 3321 may be sized to allow protrusion 2837 of fourth enclosure portion 1349 to extend therethrough in an assembled state of second fluidic interface assembly 127 such as shown in FIGS. 8 and 14. In some cases, surface 3323 (which may partially bound through-hole 3321) may abut against resting surface 2857 of protrusion 2837 in an assembled state of second fluidic interface assembly 127.

FIG. 34 schematically illustrates a perspective view of a third thermal insulator of the second fluidic interface assembly of FIG. 16 according to some embodiments.

Referring to FIG. 34, third thermal insulator 1331 may be formed as a generally irregularly shaped prism at least including first surface 3401 opposing second surface 3403 in the axial direction. Although third thermal insulator 1331 will be described having such an irregularly shaped prism configuration, embodiments are not limited thereto. For instance, third thermal insulator 1331 may have any suitable geometric configuration, such as a generally cylindrical, generally prismatic, generally conical, generally polyhedral, or the like, configuration.

First and second surfaces 3401 and 3403 of third thermal insulator 1331 may be bounded by one or more outwardly facing surfaces, such as outwardly facing surfaces (or surfaces) 3405, 3407, 3409, 3411, 3413, 3415, and 3417 that may be connected to one another. In some cases, one or more chamfered surfaces (such as chamfered surface 3419) may connect adjacent external surfaces to one another. In various implementations, third thermal insulator 1331 may include opening 3421 extending in the axial direction between second and first surfaces 3401 and 3403 and extending in the first direction from surfaces 3411 and 3413 towards surface 3405. Opening 3421 may be at least partially bounded (or otherwise defined) by one or more inwardly facing surfaces, such as inwardly facing surfaces 3423, 3425, and 3427. To this end, opening 3421 may be sized and configured to at least partially encircle second temperature-controlled enclosure 1329 in an assembled state of second fluidic interface assembly 127, such as shown in FIGS. 8, 13, and 14. This configuration may also allow third thermal insulator 1331 to be stacked between resting surfaces 2833 and 2835 of fourth enclosure portion 1349 and resting surface 1121 of first part 105 of process chamber 101 in an assembled state of process chamber 101 including second fluidic interface assembly 127. This may prevent some contact between first part 105 and second temperature-controlled enclosure 1329, and as such, may at least partially insulate first part 105 of process chamber 101 from second temperature-controlled enclosure 1329. Also, third thermal insulator 1331 may include notched (or recessed) portion 3429 formed in first surface 3401 and surface 3405.

FIG. 35 schematically illustrates a partial perspective view of a cartridge heater of at least one of first and second fluidic interface assemblies of FIGS. 15 and 16 according to some embodiments.

First and second heating elements 1317 and 1335 may, in some implementations, be formed as cartridge heaters, but embodiments are not limited thereto. In some cases, first and second heating elements 1317 and 1335 may be similarly formed having a generally cylindrical body 3501 (which may be formed of, for instance, stainless steel), heating wire 3503, and filler material 3505, such as, for example, magnesium oxide. Heating wire 3503 may extend through a central region inside body 3501. In some cases, heating wire 3503 may include coiled wire segments and/or any other suitable routing pattern within body 3501 to form, for example, a resistor or resistive load configured to generate heat according to an applied current. Filler material 3505 may be provided to fill a space between heating wire 3503 and an inner surface of body 3501. Input and output bus wires 3507 and 3509 may be electrically connected to heating wire 3503 to enable current to be applied to and flow through heating wire 3503.

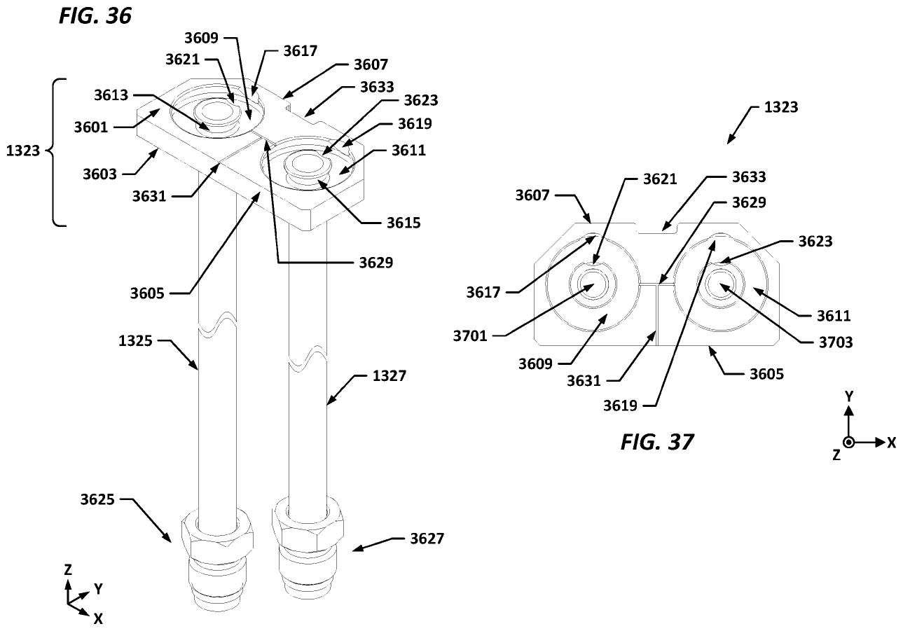

FIGS. 36 and 37 schematically illustrate perspective and orthographic views of a second fluid disconnect of the second fluidic interface assembly of FIG. 16 according to some embodiments.

Referring to FIGS. 36 and 37, second fluidic disconnect 1323 may be formed as a plate-shaped body having first surface 3601 opposing second surface 3603 in the axial direction. At least peripheral surfaces (or surfaces) 3605 and 3607 may extend between first and second surfaces 3601 and 3603 in the axial direction. First and second through-holes 3701 and 3703 may extend from first surface 3601 through second surface 3603 in the axial direction. It is also noted that second fluidic disconnect 1323 may include recessed openings 3609 and 3611 in first surface 3601 that extend in the axial direction towards second surface 3603. In some cases, recessed openings 3609 and 3611 may have generally annular configurations with protrusions 3613 and 3615 being respectively formed within an inner circular area of recessed openings 3609 and 3611. In this manner, recessed openings 3609 and 3611 may be configured to respectively support gaskets 2705 and 2707 at least partially therein. One or more first tooling notches (such as first tooling notches 3617 and 3619) may be formed in first surface 3601 and may be arranged at or near outer boundaries of recessed openings 3609 and 3611.

One or more second tooling notches (such as second tooling notches 3621 and 3623) may be formed in protrusions 3613 and 3615 at or near inner boundaries of recessed openings 3609 and 3611. It is noted that first and second tooling notches 3617-3623 may allow gaskets 2705 and 2707 to be more easily removed from recessed openings 3609 and 3611 using a tool, such as a gasket picker.

According to some embodiments, when process chamber 101 is arranged in the first configuration (such as the configuration shown in FIG. 1), first surface 2601 of first fluidic disconnect 1305 may mate with first surface 3601 of second fluidic disconnect 1323 in a manner that first and second conduits 1307 and 1325 become fluidically connected with one another and third and fourth conduits 1309 and 1327 become fluidically connected with one another. It is also noted that gaskets 2705 and 2707 (shown in phantom in FIG. 27 and that may be at least partially supported within recessed openings 3609 and 3611) may be at least partially compressed between first and second fluidic disconnects 1305 and 1323 to enhance a sealing effect therebetween. Gaskets 2705 and 2707 may respective encircle first and second through-holes 3701 and 3703 to at least fluidically isolate second and fourth conduits 1325 and 1327 from one another within second fluidic disconnect 1323.

In some implementations, proximal ends of second and fourth conduits 1325 and 1327 may be fluidically and structurally connected to first and second through-holes 3701 and 3703 via connection points (or connectors) similar to connection points 2605 and 2607 of first fluidic disconnect 1305. Distal ends of second and fourth conduits 1325 and 1327 may respectively include corresponding fluidic disconnects (such as quick disconnects) 3625 and 3627 to allow second fluidic disconnect 1323 to be installed and/or replaced in system 103 relatively easily. It is also noted that first surface 3601 of second fluidic disconnect 1323 may include one or more leak detection grooves (such as leak detection grooves 3629 and 3631) fluidically connected to first and second through-holes 3701 and 3703. In some embodiments, leak detection groove 3629 may extend in the second direction and may fluidically connect first and second through-holes 3701 and 3703 to one another in the absence of gaskets 2705 and 2707. Leak detection groove 3631 may extend in the first direction, and may include a distal end fluidically connected to leak detection groove 3629 and a proximal end fluidically connected to an ambient environment via surface 3605. In response to a failure of at least one of gaskets 2705 and 2707, fluid flowing through a corresponding flow path (or fluidic passageway) traversing a corresponding one of first and second through-holes 3701 and 3703 may be able to flow from leak detection grooves 3629 and 3631 to alert a user of the failure.

According to various embodiments, surfaces 2805 and 3309 of third and fourth enclosure portions 1347 and 1349 may abut against second surface 3603 in an assembled state of second fluidic interface assembly 127. In addition, second surface 3603 and surface 3607 of second fluidic disconnect 1323 may also include recessed (or notched) portion 3633.

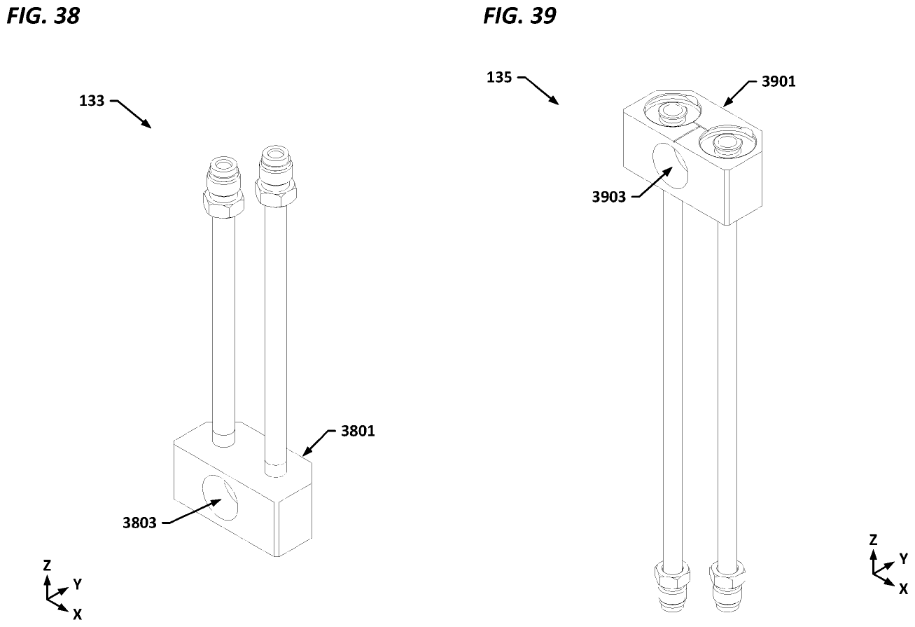

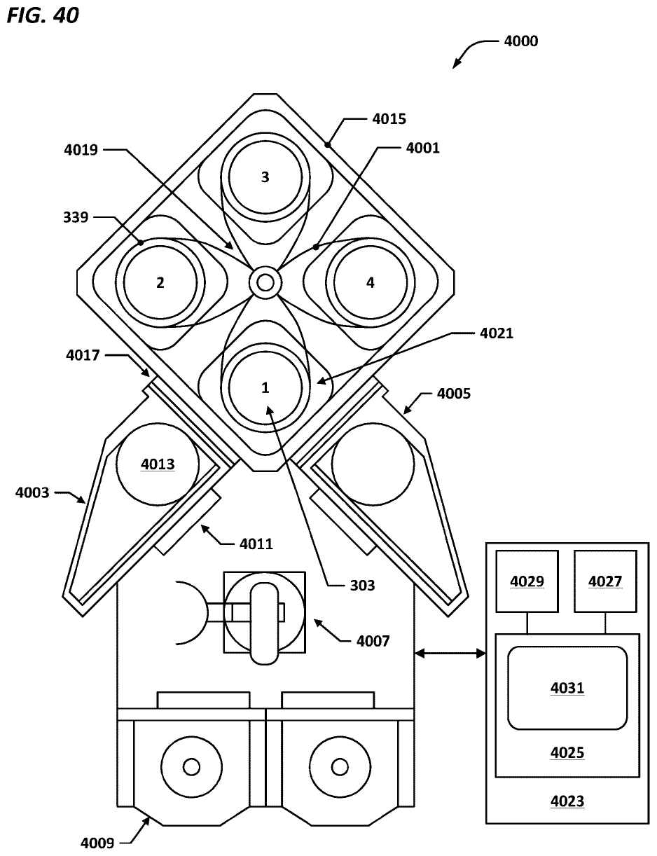

FIGS. 38 and 39 schematically illustrate perspective views of third and fourth fluidic disconnects of the semiconductor process chamber of FIG. 5 according to some embodiments Referring to FIG. 38, third fluidic disconnect 3801 may be formed similar to first fluidic disconnect 1305, but the body portion of third fluidic disconnect 3801 may be thicker than the body portion of first fluidic disconnect 1305 in the axial direction and may include through-hole 3803 extending therethrough in the first direction. Through-hole 3803 may be configured to allow a fastener to extend therethrough and engage with opening 1005 in second part 107 of process chamber 101. This may allow third fluidic disconnect 3801 to be structurally connected to second part 107. Moreover, third fluidic disconnect 3801 may omit recessed portion 2613 formed in first fluidic disconnect 1305. A remainder of the features of third fluidic disconnect 3801 may be similar to the features of first fluidic disconnect 1305, except third fluidic disconnect 3801 may not abut against a temperature-controlled enclosure and may be associated with delivery conduit 469 and divert flow path 141 versus first and third conduits 1307 and 1309. As such, duplicative descriptions will be omitted to avoid obscuring embodiments described herein.

As seen in FIG. 39, fourth fluidic disconnect 3901 may be formed similar to second fluidic disconnect 1323, but the body portion of fourth fluidic disconnect 3901 may be thicker than the body portion of second fluidic disconnect 1323 in the axial direction and may include through-hole 3903 extending therethrough in the first direction. Through-hole 3903 may be configured to allow a fastener to extend therethrough and engage with opening 1133 in first part 105 of process chamber 101. This may allow fourth fluidic disconnect 3901 to be structurally connected to first part 105. Moreover, fourth fluidic disconnect 3901 may omit recessed portion 3633 formed in second fluidic disconnect 1323. A remainder of the features of fourth fluidic disconnect 3901 may be similar to the features of second fluidic disconnect 1323, except fourth fluidic disconnect 3901 may not abut against a temperature-controlled enclosure and may be associated with delivery conduit 469 and divert flow path 141 versus second and fourth conduits 1325 and 1327. As such, duplicative descriptions will be omitted to avoid obscuring embodiments described herein.

### Multi-Station Processing Tool

FIG. 40 schematically illustrates a multi-station processing tool according to some embodiments.

In some implementations, multi-station processing tool 4000 can include an inbound load lock 4003 and an outbound load lock 4005, either or both of which may include a plasma source and/or an ultraviolet (UV) source. Robot 4007, at atmospheric pressure, is configured to move wafers from a cassette loaded through pod 4009 into inbound load lock 4003 via an atmospheric port 4011. Wafer 303 is placed by robot 4007 on pedestal 4013 in inbound load lock 4003, atmospheric port 4011 is closed, and inbound load lock 4003 is pumped down. In instances in which inbound load lock 4003 includes a remote plasma source, wafer 303 may be exposed to a remote plasma treatment in inbound load lock 4003 prior to being introduced into process chamber 4015. In some embodiments, process chamber 101 may form a portion of process chamber 4015. Further, wafer 303 may be heated in inbound load lock 4003 to, for example, remove moisture and/or adsorbed gases. Next, chamber transport port 4017 to process chamber 4015 is opened, and another robot 4019 places wafer 303 into the reactor on a pedestal of a first station shown in the reactor for processing. While the implementation depicted in FIG. 40 includes load locks, it will be appreciated that, in some implementations, direct entry of wafer 303 into a processing station may be provided.

As seen in FIG. 40, process chamber 4015 includes four process stations, numbered 1 to 4. Each station has a temperature-controlled pedestal (such as temperature-controlled pedestal 4021 of station 1), and gas line inlets. It will be appreciated that, in some cases, each process station may have different or multiple purposes. For example, in some embodiments, a process station may be switchable between a chemical vapor deposition (CVD) and PECVD process mode. In another example, deposition operations, e.g., PECVD operations, may be performed in one station, while exposure to UV radiation for UV curing may be performed in another station. In some cases, deposition and UV curing may be performed in the same station. Further, although process chamber 4015 shown as including four stations, embodiments are not limited thereto. For example, process chamber 4015 may have any suitable number of stations, such as five or more stations, or three or less stations.

Multi-station processing tool 4000 may include a wafer handling system (e.g., robot 4019 including spider forks 4001) for transferring and/or positioning wafers within process chamber 4015. In some embodiments, the wafer handling system may transfer wafers between various process stations and/or between a process station and a load lock. It is contemplated, however, that any suitable wafer handling system may be employed, such as, for example, wafer carousels, other wafer handling robots, etc. Further, multi-station processing tool 4000 may include (or otherwise be coupled to) a system controller 4023 employed to control process conditions and hardware states of multi-station processing tool 4000. System controller 4023 may include one or more memory devices 4025, one or more mass storage devices 4027, and one or more processors 4029. Each processor 4029 may include a central processing unit (CPU) or computer, analog, and/or digital input/output connections, stepper motor controller boards, etc.

In some embodiments, system controller 4023 controls each of the activities of multi-station processing tool 4000. For instance, system controller 4023 may execute system control software 4031 stored in mass storage device 4027, loaded into memory device 4025, and executed by processor 4029. Alternatively, control logic may be hard coded in system controller 4023. Application specific integrated circuits (ASIC), programmable logic devices (e.g., field-programmable gate arrays (FPGAs)) and/or the like may be used for these purposes. In the following discussion, wherever “software” or “code” is used, functionally comparable hard coded logic may be used in its place. System control software 4031 may include instructions for controlling the relative displacement between first and second parts 105 and 107 of a process chamber, timing, mixture of gases, gas flow rates, conductance, temperatures of components forming a vapor-phase delivery system (such as system 103), chamber and/or station pressure, chamber and/or station temperature, wafer temperature, target power levels, RF power levels, substrate pedestal, chuck and/or susceptor position, and other parameters of a particular process performed by multi-station processing tool 4000. For example, various process tool component subroutines or control objects may be written to control operation of the process tool components used to carry out various process tool processes. System control software 4031 may be coded in any suitable computer readable programming language.

In some embodiments, system control software 4031 may include input/output control (IOC) sequencing instructions for controlling the various parameters described above. Other computer software and/or programs stored on mass storage device 4027 and/or memory device 4025 associated with system controller 4023 may be employed in some embodiments. Examples of programs or sections of programs for this purpose include a substrate positioning program, a process gas control program, a pressure control program, a heater control program, a cooler control program, and a plasma control program.

A substrate positioning program may include program code for process tool components that are used to load and orientate wafer 303 on pedestal 4021 and to control the spacing between wafer 303 and other parts of multi-station processing tool 4000.

A process gas control program may include code for controlling gas composition (e.g., silicon-containing gases, oxygen-containing gases, nitrogen-containing gases, dilution (or inert) gases, etc.) flow rates, flow conductances, and optionally for flowing gas into one or more process stations prior to deposition to stabilize the pressure in the process station. The process gas control program may additionally or alternatively include code for controlling delivery of vapor-phase precursor that may exhibit a solid-or liquid-phase at ambient temperature and pressure conditions. A pressure control program may include code for controlling the pressure in the process station by regulating, for example, a throttle valve in an exhaust system of the process station, a gas flow into the process station via vapor-phase delivery system 103, and/or the like.

A heater control program may include code for controlling current to one or more heating units used to heat a pedestal (e.g., pedestal 4021), a gas distributor (e.g., gas distributor 311) of process chamber 4015, conduits and/or other components of vapor-phase delivery system 103, etc. Additionally or alternatively, the heater control program may control delivery of a heat transfer gas (such as helium) to a gas distributor, and, thereby, to wafer 303.

A cooling control program may include code for controlling a flow rate of conductive cooling fluid through a cooling unit used to extract heat from a pedestal (e.g., pedestal 4021) and/or a gas distributor (e.g., gas distributor 311) of process chamber 4015, and, thereby, transfer such thermal energy to, for instance, a waste heat capturing, storage, recycling, and/or disposing system. The flow of the cooling fluid through the cooling unit may also extract heat from wafer 303.

A plasma control program may include code for setting RF power levels applied to the process electrodes in one or more process stations in accordance with various embodiments.

A pressure control program may include code for maintaining pressure in a reaction chamber in accordance with various embodiments.

In some embodiments, a user interface may be provided in association with system controller 4023. The user interface may include a display screen, graphical software displays of the apparatus and/or process conditions, and user input devices, such as pointing devices, keyboards, touch screens, microphones, etc.

In some embodiments, parameters adjusted by system controller 4023 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 4023 from various process tool sensors, such as first through fourth thermocouples 1319, 1321, 1337, and 1339. The signals for controlling the process may be output on analog and/or digital output connections of multi-station process tool 4000. Non-limiting examples of process tool sensors that may be monitored include mass flow controllers, pressure sensors (such as manometers), thermocouples, etc. Appropriately programmed feedback and control algorithms may be used with data from the sensors to maintain process conditions.

System controller 4023 may provide program instructions for implementing one or more of the above-described processes. The program instructions may control a variety of process parameters, such as direct current (DC) power level, RF bias power level, pressure, temperature, etc. The instructions may control the parameters to operate deposition of film stacks of a stress compensation layer according to various embodiments.

System controller 4023 will typically include one or more memory devices and one or more processors configured to execute the instructions so that the apparatus will perform a method in accordance with some embodiments. In some instances, machine-readable media containing instructions for controlling process operations in accordance with various embodiments may be coupled to system controller 4023.

In some embodiments, system controller 4023 may be part of a system, which may be part of at least one of the above-described examples. Such systems may include semiconductor processing equipment, including a processing tool or tools, a chamber or chambers, a platform or platforms for processing, and/or specific processing components (e.g., a wafer pedestal, a gas flow system, a thermal management system, etc.). The systems discussed above may be integrated with electronics for controlling their operation before, during, and/or after processing of a semiconductor wafer or substrate. The electronics may be referred to as the “controller,” which may control various components or subparts of the system or systems. For instance, system controller 4023, depending on the processing requirements and/or the type of system, may be programmed to control any of the processes disclosed herein, including the delivery of processing gases, temperature settings (e.g., heating and/or cooling), valve operation, flow adjuster operation, light source control for radiative heating, pressure settings, vacuum settings, power settings, RF generator settings, RF matching circuit settings, frequency settings, flow rate settings, fluid delivery settings, positional and operational settings, wafer transfers into and out of a tool or chamber and other transfer tools and/or load locks connected to or interfaced with a specific system. In this manner, system controller 4023 may be configured to control, among other systems, the various actuators and motors of a wafer processing system and flow adjusters of a fluid delivery system.

Broadly speaking, system controller 4023 may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to system controller 4023 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, dies of a wafer, etc.

System controller 4023, in some implementations, may be a part of or coupled to a computer that is integrated with, coupled to the system, otherwise networked to the system, or a combination thereof. For example, system controller 4023 may be in the “cloud” or all or a part of a fab host computer system, which can allow for remote access of wafer processing.

The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It is to be understood that the parameters may be specific to the type of process to be performed and the type of tool that the controller is configured to interface with or control. Thus, as described above, system controller 4023 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and/or any other semiconductor processing system that may be associated or used in the fabrication and/or manufacturing of semiconductor wafers.

As noted above, depending on the process step or steps to be performed by the tool, system controller 4023 might communicate with one or more of other tool circuits or modules, other tool components, cluster tools, other tool interfaces, adjacent tools, neighboring tools, tools located throughout a factory, a main computer, another controller, and/or tools used in material transport that bring containers of wafers to and from tool locations and/or load ports in a semiconductor manufacturing factory.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. The apparatus also includes a cover plate detachably coupled to the second part. The cover plate includes a surface facing the recessed region of the second part in a direction transverse to the axial direction and the surface of the cover plate is spaced apart from the second temperature-controlled enclosure in the direction. In one embodiment, the second temperature-controlled enclosure at least partially encircles and is in contact with the fourth conduit; the second temperature-controlled enclosure is further configured, by way of the second heater, to transfer thermal energy to the fourth conduit; and the thermal energy transferred to the fourth conduit raises a temperature of the fourth conduit at least to the vaporization temperature of the precursor. In one example, the apparatus also includes a third fluidic interface assembly and a fourth fluidic interface assembly. The third fluidic interface assembly includes a third fluidic disconnect structurally connected to the first part; a fifth conduit extending in the axial direction and comprising a first end structurally connected to the third fluidic disconnect; and a seventh conduit extending in the axial direction and comprising a first end structurally connected to the third fluidic disconnect. The fourth fluidic interface assembly includes a fourth fluidic disconnect structurally connected to second part; a sixth conduit extending in the axial direction and comprising a first end structurally connected to the fourth fluidic disconnect; and an eighth conduit extending in the axial direction and comprising a first end structurally connected to the fourth fluidic disconnect. In the first configuration, the third fluidic disconnect and the fourth fluidic disconnect are configured to fluidically connect to: form, by way of the fifth conduit and the sixth conduit, a third fluidic passageway spanning across the contact interface and form, by way of the seventh conduit and the eighth conduit, a fourth fluidic passageway spanning across the contact interface. Also, the third fluidic passageway is configured to supply at least one gas to the gas distributor and the fourth fluidic passageway is configured to divert the at least one gas to a scrubbed exhaust. In one case of the example, neither the third fluidic interface assembly nor the fourth fluidic interface assembly includes a heater; and the third fluidic interface assembly and the fourth fluidic interface assembly are disposed adjacent to the first fluidic interface assembly and the second fluidic interface assembly.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. In these embodiments, the first fluidic passageway is configured to supply the one or more process gases to the gas distributor. Also, the first temperature-controlled enclosure includes a first enclosure portion and a second enclosure portion coupled to the first enclosure portion. The first enclosure portion includes a first surface and a second surface opposing the first surface in a first direction transverse to the axial direction and facing the first conduit in a second direction opposite the first direction. The second enclosure portion includes a third surface and a fourth surface opposing the third surface in the second direction, the fourth surface facing the second surface in the first direction and comprising a first channel configured to receive a portion of the first conduit therein. The first fluidic interface assembly also includes one or more thermal insulators configured to at least partially thermally insulate the first part from the first temperature-controlled enclosure. In one embodiment, the one or more thermal insulators includes quartz. In one embodiment, the one or more thermal insulators includes a first thermal insulator disposed between the first enclosure portion and a first corresponding portion of the first part. In one embodiment, the through-hole in the first part extends in the axial direction; the through-hole comprises an opening extending in a direction transverse to the axial direction; and the first thermal insulator abuts against a first surface of the protrusion in the fourth surface of the second enclosure portion and a corresponding surface of the opening in the through-hole in the first part. In one embodiment, the one or more thermal insulators comprise a second thermal insulator disposed between the second enclosure portion and a second corresponding portion of the first part. In one embodiment, the second thermal insulator comprises a first through-hole aligned with the second through-hole in the second enclosure portion; the first through-hole in the second thermal insulator is configured to receive the second fastener therethrough; and the second thermal insulator comprises the one or more corresponding alignment features configured to interface with the one or more alignment features of the third surface of the second enclosure portion.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. In these embodiments, the first fluidic passageway is configured to supply the one or more process gases to the gas distributor. Also, the first temperature-controlled enclosure includes a first enclosure portion and a second enclosure portion coupled to the first enclosure portion. The first enclosure portion includes a first surface and a second surface opposing the first surface in a first direction transverse to the axial direction and facing the first conduit in a second direction opposite the first direction. The second enclosure portion includes a third surface and a fourth surface opposing the third surface in the second direction, the fourth surface facing the second surface in the first direction and comprising a first channel configured to receive a portion of the first conduit therein. In one embodiment, first enclosure portion comprises a fifth surface extending between the first surface and the second surface; the second enclosure portion comprises a sixth surface extending being the third surface and the fourth surface; and the first fluidic disconnect abuts against the fifth surface and the sixth surface. In one embodiment, the first enclosure portion and the second enclosure portion include aluminum.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. In these embodiments, the first fluidic passageway is configured to supply the one or more process gases to the gas distributor. Also, the second temperature-controlled enclosure includes a third enclosure portion and fourth enclosure portion. The third enclosure portion includes a seventh surface and an eighth surface opposing the seventh surface in a second direction transverse to the axial direction and facing the second conduit in a first direction opposite the second direction The fourth enclosure portion includes a ninth surface and a tenth surface opposing the ninth surface in the first direction, the tenth surface facing the eighth surface in the second direction. The tenth surface including a second channel configured to receive a portion of the second conduit therein. In one embodiment, the third enclosure portion comprises a plurality of second openings in the eighth surface; the fourth enclosure portion comprises a plurality of second through-holes extending between the ninth surface and the tenth surface; each of the second through-holes is respectively aligned with a corresponding second opening of the second openings; and the second temperature-controlled enclosure further comprises a plurality of second fasteners, each of the second fasteners extending through a respective second through-hole of the second through-holes and engaging with the corresponding second opening aligned with the respective second through-hole. In one embodiment, the fourth enclosure portion includes a first chamfered surface at a first side of the ninth surface and a second chamfered surface at a second side of the ninth surface, the first chamfered surface and the second chamfered surface extending between the ninth surface and the tenth surface.

Also, the second temperature-controlled enclosure further includes at least one thermocouple connected to one of the first chamfered surface and the second chamfered surface. In one case, the at least one thermocouple comprises a third thermocouple connected to the first chamfered surface and a fourth thermocouple connected to the second chamfered surface. In one embodiment, the tenth surface of the fourth enclosure portion comprises a protrusion extending in the second direction; the fourth enclosure portion comprises a fourth through-hole extending from the ninth surface through the protrusion; the fourth through-hole is configured to receive a third fastener therethrough; and the third fastener is configured to engage with the second part to structurally connect the second temperature-controlled enclosure to the second part. In one case, the third enclosure portion comprises a fifth through-hole extending between the seventh surface and the eighth surface and the fifth through-hole is configured to receive the protrusion in the tenth surface of the fourth enclosure portion therethrough. In one implementation of this embodiment, the fourth thermal insulator comprises a second through-hole aligned with the fourth through-hole in the fourth enclosure portion and the second through-hole in the fourth thermal insulator is configured to receive the third fastener therethrough. In one case, the third thermal insulator is stacked between the fourth thermal insulator and the resisting surface extending between the first recessed region and the second recessed region of the second part. In one embodiment, the second fluidic interface assembly further comprises one or more thermal insulators configured to at least partially thermally insulate the second part from the second temperature-controlled enclosure. In one case, the one or more thermal insulators comprise quartz. In another case, the one or more thermal insulators comprise a third thermal insulator disposed between the fourth enclosure portion and a first corresponding portion of the second part. In another case, the one or more thermal insulators comprise a fourth thermal insulator disposed between the fourth enclosure portion and a second corresponding portion of the second part. In another case, the tenth surface of the fourth enclosure portion comprises a protrusion extending in the second direction; the fourth enclosure portion comprises a fourth through-hole extending from the ninth surface through the protrusion; the fourth through-hole is configured to receive a third fastener therethrough; and the third fastener is configured to engage with the second part to structurally connect the second temperature-controlled enclosure to the second part. In one example of this case, the third enclosure portion comprises a fifth through-hole extending between the seventh surface and the eighth surface; and the fifth through-hole is configured to receive the protrusion in the tenth surface of the fourth enclosure portion therethrough. In one embodiment, the third enclosure portion comprises an eleventh surface extending between the seventh surface and the eighth surface; the fourth enclosure portion comprises a twelfth surface extending being the ninth surface and the tenth surface; and the second fluidic disconnect abuts against the eleventh surface and the twelfth surface. In one embodiment, the third enclosure portion and the fourth enclosure portion comprises aluminum.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. The apparatus also includes a cover plate detachably coupled to the second part. The cover plate includes a surface facing the recessed region of the second part in a direction transverse to the axial direction and the surface of the cover plate is spaced apart from the second temperature-controlled enclosure in the direction. The second temperature-controlled enclosure is structurally connected to the second part at least partially within a recessed region of the second part. Also, the recessed region of the second part comprises a first recessed region, a second recessed region recessed further into the second part than the first recessed region, and a resting surface extending between the first recessed region and the second recessed region; in a view transverse to the axial direction, the fourth enclosure portion has a T-shape including a web portion extending in the axial direction and flange portions extending in directions transverse to the axial direction; and the third thermal insulator is stacked between the resisting surface of the recessed region and first surfaces of each of the protrusion in the tenth surface of the fourth enclosure portion and the flange portions of the fourth enclosure portion. In one example, the third thermal insulator includes a C-shaped configuration at least partially encircling the web portion of the fourth enclosure portion.

Certain embodiments pertain to an apparatus that includes a semiconductor process chamber having a first part and a second part moveably connected to the first part in a first configuration, the first part and the second part defining an enclosure in association with the first configuration. The apparatus also includes at least one gas distributor configured to distribute one or more process gases in the enclosure and a first fluidic interface assembly. The first fluidic interface assembly also includes a first fluidic disconnect, a first conduit extending in an axial direction and comprising a first end structurally connected to the first fluidic disconnect, a first temperature-controlled enclosure at least partially encircling and in contact with the first conduit, and a second fluidic interface assembly structurally connected to the second part. The first temperature-controlled enclosure is structurally connected to the first part and comprises a first heater. The second fluidic interface assembly includes a second fluidic disconnect and a second conduit extending in the axial direction and comprising a first end structurally connected to the second fluidic disconnect. Also, at least one of the first part and the second part is moveable between the first configuration and a second configuration. In the second configuration, the first part and the second part are spaced apart from one another in the axial direction. In the first configuration, the first fluidic disconnect and the second fluidic disconnect are configured to fluidically connect to form, by way of the first conduit and the second conduit, a first fluidic passageway spanning across a contact interface between the first part and the second part. Also, the first temperature-controlled enclosure is configured, by way of the first heater, to transfer thermal energy to the first conduit. In addition, the thermal energy transferred to the first conduit raises a temperature of the first conduit above a vaporization temperature of a precursor of the one or more process gases. In one of these embodiments, a second end of the first conduit is fluidically connected to the gas distributor and a second end of the second conduit is fluidically connected to a source of the precursor. In one of these embodiments, the first part forms a lid of the semiconductor process chamber. In one of these embodiments, the first part and the second part comprise aluminum.

### Additional And/or Alternative Embodiments

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Accordingly, the term “substantially” as used herein, unless otherwise specified, means within 5% of a referenced value. For example, substantially perpendicular means within ±5% of parallel.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element, it may be directly on, directly connected to, or directly coupled to the other element or at least one intervening element may be present. When, however, an element is referred to as being “directly on,” “directly connected to,” or “directly coupled to” another element, there are no intervening elements present. Other terms and/or phrases if used herein to describe a relationship between elements should be interpreted in a like fashion, such as “between” versus “directly between,” “adjacent” versus “directly adjacent,” “on” versus “directly on,” etc. Further, the term “connected” may refer to physical, electrical, and/or fluid connection. To this end, for the purposes of this disclosure, the phrase “fluidically connected” is used with respect to volumes, plenums, holes, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, etc., that is fluidically connected with at least two other components, volumes, plenums, holes, etc., such that fluid flowing from one of those other components, volumes, plenums, holes etc., to the other or another of those components, volumes, plenums, holes, etc., would first flow through the “fluidically interposed” component before reaching that other or another of those components, volumes, plenums, holes, etc. For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures fluidically are interposed between the two elements that might potentially interrupt fluid flow between the two fluidic elements. For example, in a flow path having a first valve, a second valve, and a third valve arranged sequentially therealong, the first valve would be fluidically adjacent to the second valve, the second valve fluidically adjacent to both the first and third valves, and the third valve fluidically adjacent to the second valve.

For the purposes of this disclosure, “at least one of X, Y, . . . and Z” and “at least one selected from the group consisting of X, Y, . . . and Z” may be construed as X only, Y only, . . . Z only, or any combination of two or more of X, Y, . . . and Z, such as, for instance, XYZ, XYY, YZ, and ZZ. As used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . or (1), (2), (3), . . . or the like, in this disclosure and accompanying claims, is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “between,” as used herein and when used with a range of values, is to be understood, unless otherwise indicated, as being inclusive of the start and end values of that range. For example, between 1 and 5 is to be understood as inclusive of the numbers 1, 2, 3, 4, and 5, not just the numbers 2, 3, and 4.

As used herein, the phrase “operatively connected” is to be understood as referring to a state in which two components and/or systems are connected, either directly or indirectly, such that, for example, at least one component or system can control the other. For instance, a controller may be described as being operatively connected with (or to) a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely will not supply such power directly to the resistive heating unit due to the current(s) involved, but it is to be understood that the controller is nonetheless operatively connected with the resistive heating unit.

As used herein, the singular forms, “a,” “an,” and “the” are intended to include the plural forms as well, unless the context clearly indicates otherwise. It is also to be understood that the phrases “for each <item>of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced.

For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items-it is to be understood that a set or a subset can encompass only one member or multiple members (unless the context indicates otherwise). In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional views, isometric views, perspective views, plan views, and/or exploded illustrations that are schematic depictions of idealized embodiments and/or intermediate structures. As such, variations from the shapes of the illustrations as a result of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and are not to be interpreted in an idealized or overly formal sense, unless expressly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the inventive concepts. Further, the blocks, units, and/or modules of some embodiments may be physically combined into more complex blocks, units, and/or modules without departing from the teachings of the disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered as illustrative and not as restrictive, and embodiments are not to be limited to the details given herein.

1. An apparatus comprising:
a semiconductor process chamber comprising a first part and a second part moveably connected to the first part in a first configuration, the first part and the second part defining an enclosure in association with the first configuration;
at least one gas distributor configured to distribute one or more process gases in the enclosure; and
a first fluidic interface assembly comprising:
a first fluidic disconnect;
a first conduit extending in an axial direction and comprising a first end structurally connected to the first fluidic disconnect;
a first temperature-controlled enclosure at least partially encircling and in contact with the first conduit, wherein the first temperature-controlled enclosure is structurally connected to the first part and comprises a first heater; and
a second fluidic interface assembly structurally connected to the second part, the second fluidic interface assembly comprising:
a second fluidic disconnect; and
a second conduit extending in the axial direction and comprising a first end structurally connected to the second fluidic disconnect,
wherein:
at least one of the first part and the second part is moveable between the first configuration and a second configuration;
in the second configuration, the first part and the second part are spaced apart from one another in the axial direction;
in the first configuration, the first fluidic disconnect and the second fluidic disconnect are configured to fluidically connect to form, by way of the first conduit and the second conduit, a first fluidic passageway spanning across a contact interface between the first part and the second part;
the first temperature-controlled enclosure is configured, by way of the first heater, to transfer thermal energy to the first conduit; and
the thermal energy transferred to the first conduit raises a temperature of the first conduit above a vaporization temperature of a precursor of the one or more process gases.

2. The apparatus of claim 1, wherein the first fluidic passageway is configured to supply the one or more process gases to the gas distributor.

3. apparatus of claim 1, wherein:
the second fluidic interface assembly further comprises a second temperature-controlled enclosure at least partially encircling and in contact with the second conduit;
the second temperature-controlled enclosure is structurally connected to the second part and comprises a second heater;
the second temperature-controlled enclosure is configured, by way of the second heater, to transfer thermal energy to the second conduit; and
the thermal energy transferred to the second conduit raises a temperature of the second conduit above the vaporization temperature of the precursor.

4. The apparatus of claim 1, wherein the first temperature-controlled enclosure is structurally connected to the first part within a through-hole extending through the first part.

5. The apparatus of claim 3, wherein the second temperature-controlled enclosure is structurally connected to the second part at least partially within a recessed region of the second part.

6. The apparatus of claim 1, wherein:
the first fluidic interface assembly further comprises a third conduit having a first end structurally connected to the first fluidic disconnect;
the first temperature-controlled enclosure at least partially encircles and is in contact with the third conduit;
the second fluidic interface assembly further comprises a fourth conduit having a first end structurally connected to the second fluidic disconnect;
in the first configuration, the first fluidic disconnect and the second fluidic disconnect are further configured to fluidically connect to form, by way of the third conduit and the fourth conduit, a second fluidic passageway spanning across the contact interface between the first part and the second part;
the second fluidic passageway is fluidically connected to a scrubbed exhaust;
the first temperature-controlled enclosure is further configured, by way of the first heater, to transfer thermal energy to the third conduit; and
the thermal energy transferred to the third conduit raises a temperature of the third conduit at least to the vaporization temperature of the precursor.

7. The apparatus of claim 2, wherein the first temperature-controlled enclosure comprises:
a first enclosure portion comprising:
a first surface; and
a second surface opposing the first surface in a first direction transverse to the axial direction and facing the first conduit in a second direction opposite the first direction; and
a second enclosure portion coupled to the first enclosure portion, the second enclosure portion comprising:
a third surface; and
a fourth surface opposing the third surface in the second direction, the fourth surface facing the second surface in the first direction and comprising a first channel configured to receive a portion of the first conduit therein.

8. The apparatus of claim 7, wherein:
the first enclosure portion comprises a plurality of first openings in the second surface;
the second enclosure portion comprises a plurality of first through-holes extending between the third surface and the fourth surface;
each of the first through-holes is respectively aligned with a corresponding first opening of the first openings; and
the first temperature-controlled enclosure further comprises a plurality of first fasteners, each of the first fasteners extending through a respective first through-hole of the first through-holes and engaging with the corresponding first opening aligned with the respective first through-hole.

9. The apparatus of claim 7, wherein the third surface of the second enclosure portion comprises one or more alignment features configured to interface with one or more corresponding alignment features in at least one other component of the first temperature-controlled enclosure.

10. The apparatus of claim 7, wherein the first temperature-controlled enclosure further comprises at least one thermocouple connected to the third surface of the second enclosure portion.

11. The apparatus of claim 10, wherein the at least one thermocouple comprises:
a first thermocouple connected to the third surface of the second enclosure portion in a position overlapping the first channel in the first direction; and
a second thermocouple connected to the third surface of the second enclosure portion in a position overlapping a second channel formed in the fourth surface of the second enclosure portion, wherein the second channel is configured to receive a portion of a third conduit therein.

12. The apparatus of claim 7, wherein:
the fourth surface of the second enclosure portion comprises a protrusion extending in the first direction;
the second enclosure portion comprises a second through-hole extending from the third surface through the protrusion;
the second through-hole is configured to receive a second fastener therethrough; and
the second fastener is configured to engage with the first part to structurally connect the first temperature-controlled enclosure to the first part.

13. The apparatus of claim 12, wherein:
the first enclosure portion comprises a third through-hole extending between the first surface and the second surface; and
the third through-hole is configured to receive the protrusion in the fourth surface of the second enclosure portion therethrough.

14. The apparatus of claim 7, wherein the first fluidic interface assembly further comprises one or more thermal insulators configured to at least partially thermally insulate the first part from the first temperature-controlled enclosure.

15. The apparatus of claim 1, wherein:
the first fluidic disconnect comprises a first body having a first surface;
the second fluidic disconnect comprises a second body having a second surface facing the first surface in the axial direction;
at least one of the first body and the second body comprises a first blind opening concentrically aligned with the first conduit and the second conduit; and
the first blind opening comprises a gasket that, in the first configuration, is at least partially compressed between the first body and the second body and fluidically seals the first fluidic passageway between the first body and the second body.

16. The apparatus of claim 15, wherein:
the at least one of the first body and the second body further comprises a second blind opening concentrically aligned with the third conduit and the fourth conduit; and
the second blind opening comprises a gasket that, in the first configuration, is at least partially compressed between the first body and the second body and fluidically seals the second fluidic passageway between the first body and the second body.

17. The apparatus of claim 16, wherein the at least one of the first body and the second body further comprises one or more leak detection grooves fluidically connected to the first blind opening and the second blind opening.

18. The apparatus of claim 1, wherein a source of the precursor is an intermediary source configured to maintain the precursor in a liquid-phase during storage.

19. The apparatus of claim 18, wherein the intermediary source comprises a vaporizer configured to flow the precursor into the first fluidic passageway as a vapor.

20. The apparatus of claim 18, wherein the intermediary source is positioned at a lower elevation than the semiconductor process chamber.

21. The apparatus of claim 18, wherein:
the intermediary source is fluidically connected to a centralized source of the precursor; and
the intermediary source is further configured to replenish a supply of the precursor from the centralized source.

22. The apparatus of claim 21, wherein the centralized source is positioned at a lower elevation than the intermediary source.

23. The apparatus of claim 22, wherein:
the intermediary source is supported on a floor of a fabrication facility; and
the centralized source is supported below the floor of the fabrication facility.
